(19) United States
(12) Patent Application Publication
(10) Pub. No.: US 2004/0099216 A1
(43) Pub. Date: May 27, 2004

(54) Apparatus for modifying surface of material using ion beam

(76) Inventors: Seok-Keun Koh, Seoul (KR); Jun-Sik Cho, Seoul (KR); Young-Whoan Beag, Seoul (KR)

Correspondence Address: BIRCH STEWART KOLASCH & BIRCH, PO BOX 747, FALLS CHURCH, VA, 22040-0747, US

(21) Appl. No.: 10/701,685

(22) Filed: Nov. 6, 2003

(30) Foreign Application Priority Data
Nov. 27, 2002 (KR) 2002-74529

(51) Int. Cl. C23C 16/00

(52) U.S. Cl. 118/723 CB; 118/723 EB

(57) ABSTRACT

Disclosed is an apparatus for modifying a surface of a material enabling to improve an ion beam treated effect and efficiency of a surface modified material by installing a gas distributor distributing a reactive gas uniformly, an exhaust valve controlling an exhaust speed of the reactive gas, or a plurality of ion beam treatment areas providing various surface modification effects. The present invention includes a vacuum chamber, an ion gun generating an ion beam in the vacuum chamber, a surface-modification substrate material to which the ion beam is applied from the ion gun in the vacuum chamber, a reactive gas inlet leaving a predetermined interval from the surface-modification substrate material to supply a reactive gas, a gas distributor connected to the reactive gas inlet to maintain a partial pressure of the reactive gas uniformly on an entire surface of the surface-modification substrate material, a vacuum means for generating a vacuum of the vacuum chamber, and an exhaust valve installed at a front end of the vacuum means to control an exhaust speed of the reactive gas.

### BACKGROUND OF THE INVENTION

1. Field of the Invention

The present invention relates to an apparatus for modifying a surface of a material using an ion beam, and more particularly, to an apparatus for modifying a surface of a material enabling to improve an ion beam treated effect and efficiency of a surface modified material by installing a gas distributor distributing a reactive gas uniformly, an exhaust valve controlling an exhaust speed of the reactive gas, and/or a plurality of ion beam treatment areas providing various surface modification effects.

2. Background of the Related Art

Generally, applications of ion beam modification according to a related art include a thin film fabrication method and a surface cleaning method. Proposed for the thin film fabricating method according to the related art are ion implantation or ion irradiation using high energy (10 KeV˜several MeV), ion beam sputtering deposition carried out by irradiating ionized particles from an ion source (ion gun) generating particles of low energy (0˜several KeV) on a target to generate a demanded material, multi ion beam deposition, assisting thin film fabrication, ion-assisted deposition, and the like.

Moreover, proposed for the surface cleaning method are surface cleaning carried out by irradiating energized particles on a material surface, reactive ion beam etching carried out by injecting a reactive gas in a vacuum chamber, and the like.

Thin film fabricating method using an ion beam fabricates a thin film by adjusting a relative particle ratio of an assisting particle ion to a deposited particle, while the surface cleaning method using an ion beam accelerates a speed of cleaning, which takes long by a conventional wet reaction, by adjusting a plasma generation and a reactive gas amount to ionize the reactive gas.

FIG. 1 schematically illustrates an apparatus for modifying a surface of material using an ion beam according to a related art.

Referring to FIG. 1, a material surface modifying apparatus using an ion beam according to a related art contains a surface-modification substrate material 100, an ion gun 110 generating an ion beam IB, an assistant ion gun 111 generating an assistant ion beam AB near the ion gun 110, a holder 130 holding the surface-modification substrate material 100, a reactive gas inlet 140 through which a reactive gas is injected, an ion beam current measuring device 150 measuring an amount of an irradiated ion beam, an ion beam controller 151 controlling an amount of the irradiated ion beam, and a vacuum pump 170 generating a vacuum state inside a vacuum chamber 160.

For instance, the material surface modifying apparatus using the ion gun is implemented in a following manner that oxygen as the reactive gas is blown around the surface-modification substrate material 100 of polymer through the reactive gas inlet 140 and that Ar ions are irradiated on a surface of the surface-modification substrate material 100 through the ion gun 110 and the assistant ion gun 111. Hence, oxygen atoms supplied from the reactive gas are chemically bonded to carbon rings to generate a hydrophilic functional group on the surface of the surface-modification substrate material 100 composed of a polymer material having a carbon atom as a major component.

In another way, oxygen as the reactive gas is blown onto a surface of the surface-modification substrate material of aluminum nitride (AlN) through the reactive gas inlet 140 and Ar ions are irradiated thereon through the ion gun 110 and the assistant ion gun 111, thereby generating aluminum oxynitride (AION), which is formed by oxygen and nitrogen atoms chemically bonded to each other, on the surface of the surface-modification substrate material 100 of aluminum nitride (AlN). Hence, without affecting the surface-modification substrate material 100 itself, a new layer material is formed on the surface of the surface-modification substrate material 100 to vary the inherent properties thereof.

The ion-beam treated surface-modification material 100 may have the variations of adhesion to another material, adsorption, hydrophilic property, material surface strength, etc. In the ion assisted reaction (IAR), the particle energy having a lower energy band is generally used compared to the earlier deposition methods, and the dosage of the ion irradiation is 1×10¹³˜1×10¹⁸ ions/cm2, and the amount of the reactive gas supplied through the reactive gas inlet is also characterized in that the partial pressure around the material is higher than the total degree of vacuum in the vacuum chamber.

However, in the above-explained ion beam modification apparatus, only the surface modification by the reactive gas is considered as an important matter. Hence, the ion beam modification apparatus fails to include a gas distributor distributing a reactive gas uniformly on the surface of the surface-modification substrate material 100, an exhaust valve controlling an exhaust speed of the reactive gas, or a plurality of ion beam treatment areas providing various surface modification effects for various surface modifications. As the reactive gas inlet injecting the reactive gas into the vacuum chamber is installed in the related art ion beam modification apparatus, it is difficult to attain the uniform distribution of the reactive gas on a surface of a surface-modification substrate material having a large surface area. In such a case, the surface-modification substrate material is modified in part to reduce the efficiency of the ion beam surface modification greatly. Moreover, the related art ion beam modification apparatus fails to include an exhaust valve controlling a vacuum exhaust speed therein. An exhaust valve is generally installed at a front end of a vacuum pump. If there is no exhaust valve, an injected reactive gas stays around the surface of surface-modification substrate material for a short period of time as well as a partial pressure of the reactive gas is low. Hence, the reaction on the surface of the surface-modification substrate material fails to be sufficiently accomplished. In order to increase the ion beam modification effect, it is very important to secure a reaction time and a partial pressure of reactive gas which enable the sufficient reaction between the reactive gas and the ion-beam irradiated surface-modification substrate material by supplying the reactive gas uniformly through a reactive gas distributor and by controlling an exhaust valve.

Thus, the surface modification apparatus using the ion beam according to the related art has the following disadvantages or problems.

First of all, in carrying out the surface modification of the surface-modification substrate material by the irradiated ion beam and the reactive gas, it is difficult to accomplish the uniform surface modification since the reactive gas supplied through the reactive gas inlet fails to be distributed uniformly.

Secondly, in carrying out the surface modification of the surface-modification substrate material by the irradiated ion beam and the reactive gas, it is unable to maintain the reaction time and partial gas pressure required for bringing about a chemical reaction between the ion-irradiated surface-modification substrate material and the reactive gas since the exhaust valve controlling the vacuum exhaust speed fails to be installed therein. Hence, the effect of the surface modification is greatly reduced.

Thirdly, only one ion gun is installed in the vacuum chamber as the ion beam treatment area to take a long period of time for the surface treatment, thereby increasing a manufacturing cost.

Finally, a single ion gun and a single reactive gas inlet are installed in the vacuum chamber as the ion beam treatment area, thereby failing to provide various effects of various surface modifications according to various reactive gas supplies and vacuum conditions.

### SUMMARY OF THE INVENTION

Accordingly, the present invention is directed to an apparatus for modifying a surface of a material using an ion beam that substantially obviates one or more problems due to limitations and disadvantages of the related art.

An object of the present invention is to provide an apparatus for modifying a surface of a material using an ion beam enabling to improve an ion beam treated effect and efficiency of a surface modified material by installing a gas distributor distributing a reactive gas uniformly, an exhaust valve controlling an exhaust speed of the reactive gas, or a plurality of ion beam treatment areas providing various surface modification effects.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an apparatus for modifying a surface of a material according to the present invention includes a vacuum chamber, an ion gun generating an ion beam in the vacuum chamber, a surface-modification substrate material to which the ion beam is applied from the ion gun in the vacuum chamber, a reactive gas inlet leaving a predetermined interval from the surface-modification substrate material to supply a reactive gas, a gas distributor connected to the reactive gas inlet to maintain a partial pressure of the reactive gas uniformly on an entire surface of the surface-modification substrate material, a vacuum means for generating a vacuum of the vacuum chamber, and an exhaust valve installed at a front end of the vacuum means to control an exhaust speed of the reactive gas.

In another aspect of the present invention, an apparatus for modifying a surface of a material includes a vacuum chamber, an ion gun generating an ion beam in the vacuum chamber, a surface-modification substrate material to which the ion beam is applied from the ion gun in the vacuum chamber, a reactive gas inlet leaving a predetermined interval from the surface-modification substrate material to supply a reactive gas, a gas distributor connected to the reactive gas inlet to maintain a partial pressure of the reactive gas uniformly on an entire surface of the surface-modification substrate material, a partitioning wall separating the ion gun from the surface-modification substrate material, a vacuum means for generating a vacuum of the vacuum chamber, and an exhaust valve installed at a front end of the vacuum means to control an exhaust speed of the reactive gas.

In another aspect of the present invention, an apparatus for modifying a surface of a material includes a vacuum chamber, an ion gun generating an ion beam in the vacuum chamber, a holder operating by a motor at a location to which the ion beam is applied from the ion gun in the vacuum chamber, a powder-phased surface-modification substrate material agitated by the holder, a reactive gas inlet entering a bottom of the vacuum chamber to a periphery of the holder to supply a reactive gas, a gas distributor connected to the reactive gas inlet to maintain a partial pressure of the reactive gas uniformly on an entire surface of the surface-modification substrate material, a partitioning wall separating the ion gun from the surface-modification substrate material, a vacuum means for generating a vacuum of the vacuum chamber, and an exhaust valve installed at a front end of the vacuum means to control an exhaust speed of the reactive gas.

In another aspect of the present invention, an apparatus for modifying a surface of a material includes a vacuum chamber, at least two ion guns generating ion beams respectively in the vacuum chamber, a conveyer transferring a surface-modification substrate material having surfaces of which number corresponds to a number of the ion guns, a reactive gas inlet supplying a reactive gas, at least two gas distributors corresponding to the number of the ion guns, each of the gas distributors connected to the reactive gas inlet to maintain a partial pressure of the reactive gas uniformly on an entire surface of the surface-modification substrate material, a vacuum means for generating a vacuum of the vacuum chamber, and an exhaust valve installed at a front end of the vacuum means to control an exhaust speed of the reactive gas.

In another aspect of the present invention, an apparatus for modifying a surface of a material includes a main vacuum chamber, an auxiliary vacuum chamber connected to the main vacuum chamber to have a vacuum degree lower than that of the main vacuum chamber, an ion gun generating an ion beam in the main vacuum chamber, a surface-modification substrate material to which the ion beam is applied from the ion gun in the main vacuum chamber, a conveyer transferring the surface-modification substrate material, a reactive gas inlet leaving a predetermined interval from the surface-modification substrate material to supply a reactive gas, a gas distributor connected to the reactive gas inlet to maintain a partial pressure of the reactive gas uniformly on an entire surface of the surface-modification substrate material, a vacuum means for generating a vacuum of the main and auxiliary vacuum chambers, and an exhaust valve installed at a front end of the vacuum means to control an exhaust speed of the reactive gas.

In another aspect of the present invention, an apparatus for modifying a surface of a material includes a main vacuum chamber, an ion gun generating an ion beam in the main vacuum chamber, a plate-shaped surface-modification substrate material to which the ion beam is applied from the ion gun in the main vacuum chamber, a first auxiliary vacuum chamber at one side of the main vacuum chamber to make the surface-modification substrate material stand by or supply the main vacuum chamber with the surface-modification substrate material, a second auxiliary vacuum chamber at the other side of the main vacuum chamber to unload the surface-modification substrate material, a reactive gas inlet leaving a predetermined interval from the surface-modification substrate material to supply a reactive gas, a gas distributor connected to the reactive gas inlet to maintain a partial pressure of the reactive gas uniformly on an entire surface of the surface-modification substrate material, a vacuum means for generating a vacuum of the main, first, and second vacuum chambers, and an exhaust valve installed at a front end of the vacuum means to control an exhaust speed of the reactive gas.

In a further aspect of the present invention, an apparatus for modifying a surface of a material includes a vacuum chamber, a plurality of ion beam treatment areas having a drum located at a center of the vacuum chamber, the ion beam treatment areas separated by a plurality of partitioning walls, a plurality of ion guns generating ion beams in a plurality of the ion beam treatment areas, respectively, at least one reactive gas inlet supplying a plurality of the ion beam treatment areas with a reactive gas, respectively, at least one gas distributor connected to the reactive gas inlet to maintain a partial pressure of the reactive gas uniformly on an entire surface of a surface-modification substrate material, a conveyer transferring the surface-modification substrate material to a plurality of the ion beam treatment areas, a vacuum means for generating vacuums of the vacuum chamber and a plurality of the ion beam treatment areas independently, and an exhaust valve installed at a front end of the vacuum means to control an exhaust speed of the reactive gas.

In another further aspect of the present invention, an apparatus for modifying a surface of a material includes a vacuum chamber, a plurality of ion beam treatment areas having a drum located at a center of the vacuum chamber, the ion beam treatment areas separated by a plurality of partitioning walls, a plurality of ion guns generating ion beams in a plurality of the ion beam treatment areas, respectively, at least one reactive gas inlet supplying a plurality of the ion beam treatment areas with a reactive gas, respectively, at least one gas distributor connected to the reactive gas inlet to maintain a partial pressure of the reactive gas uniformly on an entire surface of a surface-modification substrate material, a first auxiliary vacuum chamber for attaining a high vacuum state required for supplying the vacuum chamber with the surface-modification substrate material in an atmosphere, a second auxiliary vacuum chamber for attaining a low vacuum state required for discharging the surface-modification substrate material into the atmosphere wherein the surface-modification substrate material is surface-treated in the vacuum chamber, a conveyer transferring the surface-modification substrate material, and a vacuum means for generating vacuums of the vacuum chamber and a plurality of the ion beam treatment areas independently.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 schematically illustrates an apparatus for modifying a surface of material using an ion beam according to a related art;

FIG. 2 schematically illustrates an apparatus for modifying a surface of a material using an ion beam according to a first embodiment of the present invention;

FIG. 3 schematically illustrates an apparatus for modifying a surface of a material using an ion beam according to a second embodiment of the present invention;

FIG. 4 schematically illustrates an apparatus for modifying a surface of a material using an ion beam according to a third embodiment of the present invention;

FIG. 5 schematically illustrates an apparatus for modifying a surface of a material using an ion beam according to a fourth embodiment of the present invention;

FIG. 6 schematically illustrates an apparatus for modifying a surface of a material using an ion beam according to a fifth embodiment of the present invention;

FIG. 7 schematically illustrates an apparatus for modifying a surface of a material using an ion beam according to a sixth embodiment of the present invention;

FIG. 8 schematically illustrates an apparatus for modifying a surface of a material using an ion beam according to a seventh embodiment of the present invention;

FIG. 9 schematically illustrates an apparatus for modifying a surface of a material using an ion beam according to an eighth embodiment of the present invention;

FIGS. 10A to 10C illustrate layouts of gas distributors used in the present invention; and

FIGS. 11A and FIG. 11B illustrate layouts of gas distributors each having an ion beam current measuring device used in the present invention.

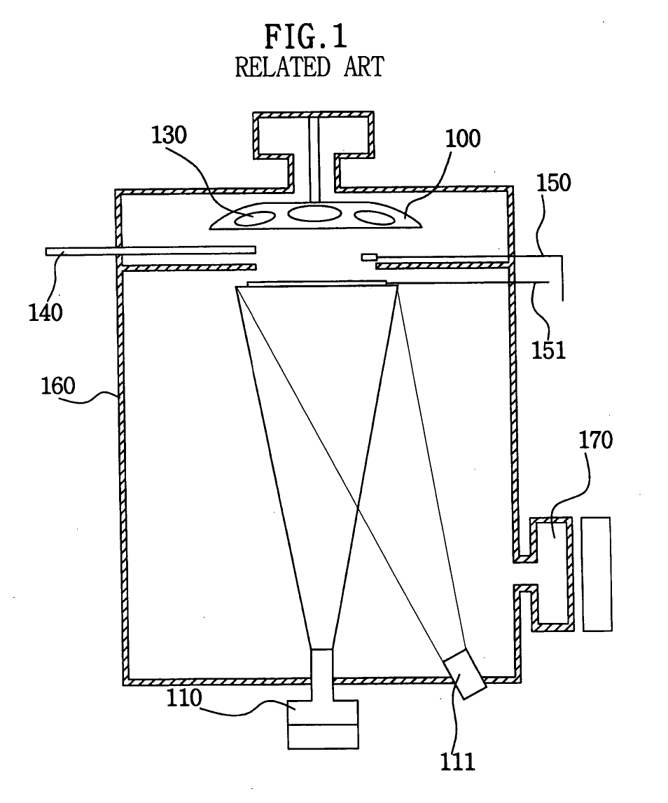

### DETAILED DESCRIPTION OF THE PREFERRED EMBODIMENTS

Reference will now be made in detail to the preferred embodiments of the present invention, examples of which are illustrated in the accompanying drawings.

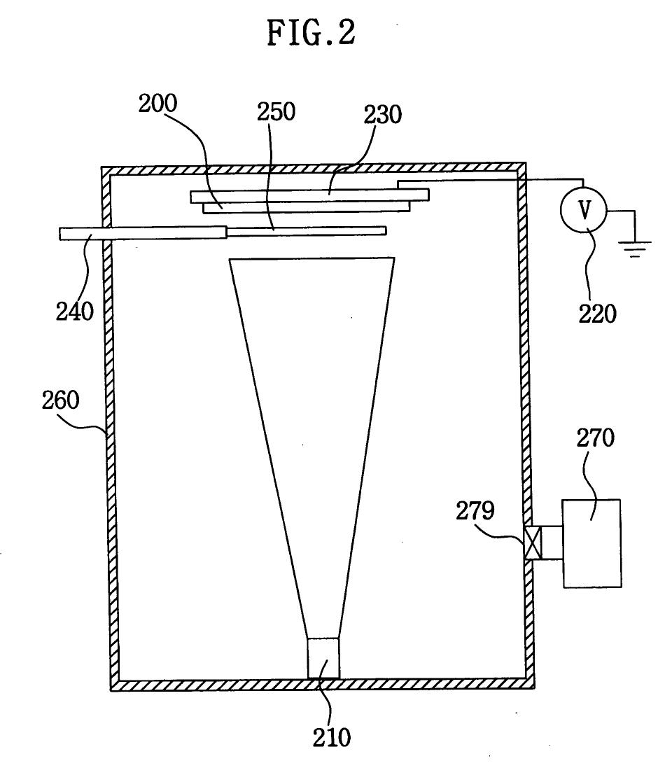

FIG. 2 schematically illustrates an apparatus for modifying a surface of a material using an ion beam according to a first embodiment of the present invention.

Referring to FIG. 2, an apparatus for modifying a surface of a material using an ion beam by applying a voltage to a surface-modification substrate material includes an ion gun 210 installed at a lower part of a vacuum chamber to generate an ion beam, a holder 230 holding a surface-modification substrate material 200, a reactive gas inlet 240 injecting a reactive gas, a gas distributor 250 connected to the reactive gas inlet 240 to maintain a partial pressure of the reactive gas on an entire surface of the surface-modification substrate material 200 uniformly, a vacuum chamber 260 facilitating a vacuum maintenance and a generation of the ion beam, a vacuum pump 270 generating a vacuum inside the vacuum chamber 260, and an exhaust valve 279 installed at a front end of the vacuum pump 270 to control a vacuum exhaust speed and an exhaust speed of the reactive gas.

The holder 230 supporting the surface-modification substrate material 200 is designed to be electrically insulated from the vacuum chamber 260 as well as apply a negative (−) or positive (+) voltage thereto.

When a power source 220 is applied to the surface-modification substrate material 200 and the ion beam is applied thereto, Ar ions (Ar⁺) emitted from the ion gun 210 are accelerated. Hence, an attraction or repulsive force is generated between the ions generated from the ion gun 210 and a surface of the surface-modification substrate material 200 to obtain a charge distortion, thereby enabling to modify a composition and a shape of the surface-modification substrate material 200.

In case that the ion beam generated from the ion gun 210 is irradiated on the surface of the surface-modification substrate material 200 and simultaneously that oxygen or nitrogen as the reactive gas is injected therein, the hydrophobic surface of the surface-modification substrate material 200 may be changed to be hydrophilic.

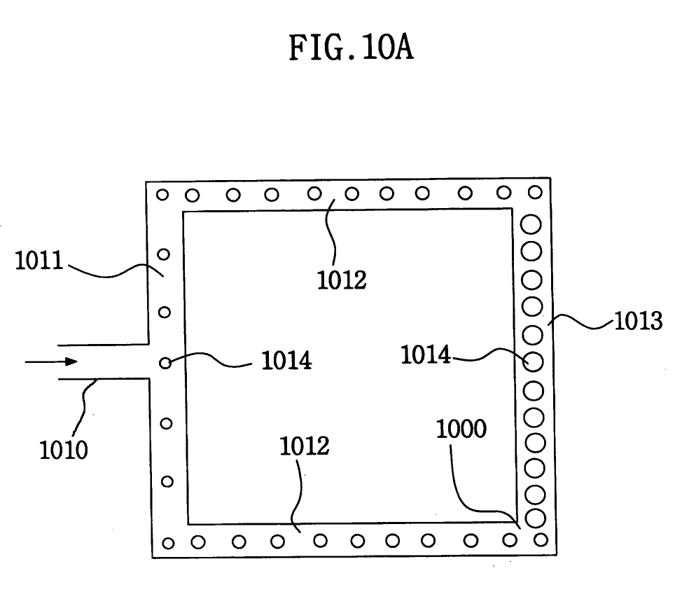

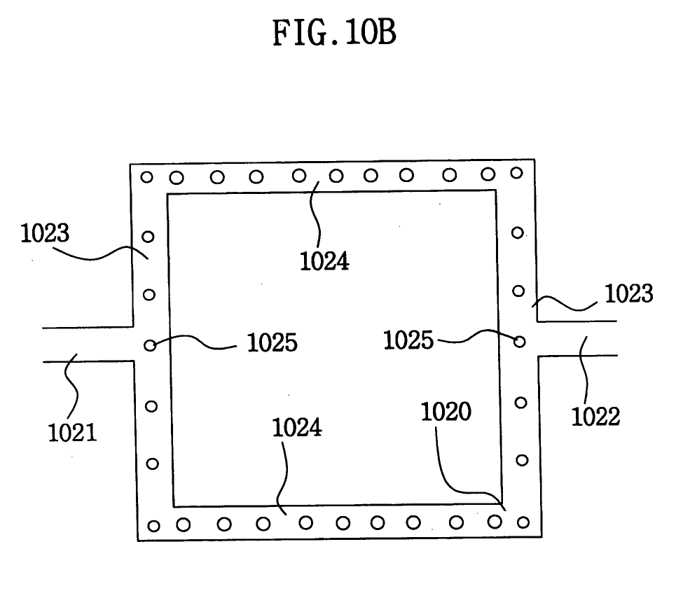

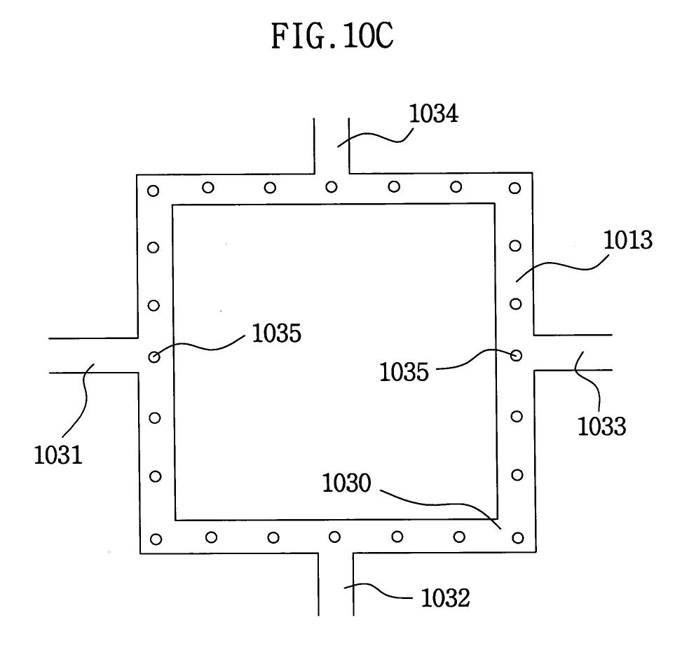

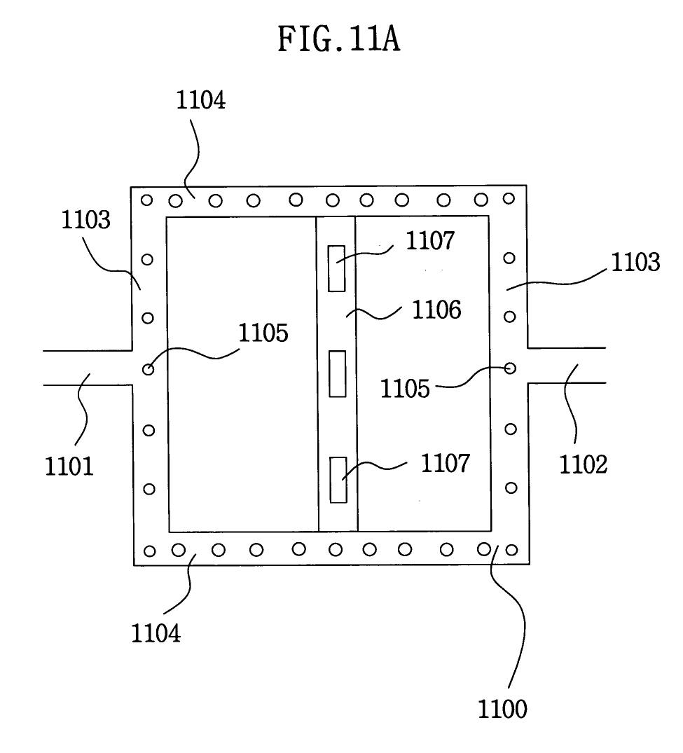

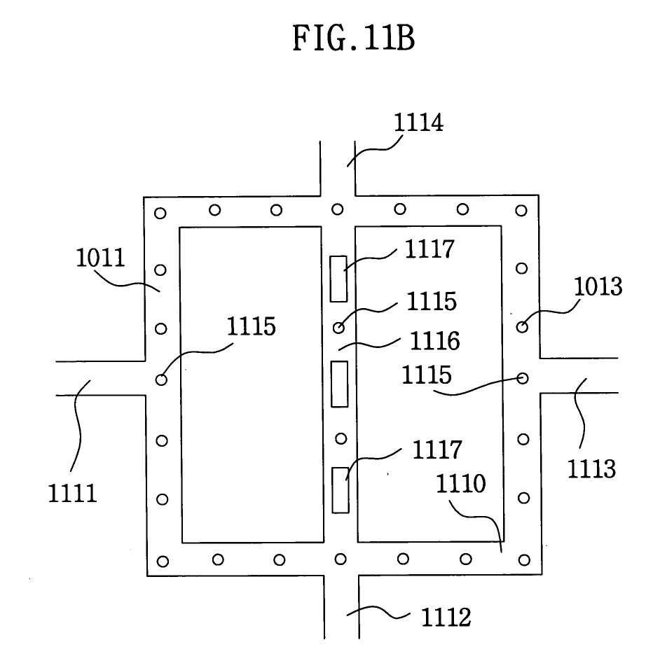

In order to prevent the case that a surface modification effect varies according to a location since the reactive gas fails to maintain a partial pressure uniformly on the surface of the surface-modification substrate material 200, the gas distributor 250 is connected to the reactive gas inlet 240 to maintain the partial pressure of the reactive gas on the entire surface of the surface-modification substrate material 200 uniformly. In FIG. 10 and FIG. 11, shown are the detailed description and layout of the gas distributor according to the first embodiment of the present invention and another detailed description and layout of a gas distributor having an ion beam current measuring device installed therein. Hence, it is able to improve an ion beam treatment effect and efficiency of the surface-modification substrate material using the gas distributors (some of them may have an ion beam current measuring device installed therein) properly and respectively. And, the corresponding shapes are exactly illustrated in FIG. 10 and FIG. 11.

The gas distributor 250 is separated from the surface-modification substrate material 200 to leave a predetermined interval in parallel from each other, and a hole (not shown in the drawing) through which the reactive gas is supplied is disposed to face the surface of the surface-modification substrate material 200.

The exhaust valve 279 is installed at the front end of the vacuum pump 270 to control the vacuum exhaust speed and the exhaust speed of the reactive gas to maximize a time that the reactive gas stays around the surface-modification substrate material 200 and the partial gas pressure of the reactive gas. Thus, the exhaust valve 279 maximizes a reaction between the surface-modification substrate material 200 having the ion beam irradiated thereon and the reactive gas, thereby enabling to improve the ion beam treatment effect and efficiency thereof.

The surface-modification substrate material 200 is a material including a metal, ceramic, or a polymer material, and may have a curved surface. And, the organic material uses a polymer material combined with a material such as carbon, oxygen, nitrogen, fluorine, silicon, and the like.

The surface-modification substrate material 200 is the polymer material containing carbon and hydrogen and selected from the group consisting of PE, PP, PS, etc., the polymer material containing carbon, hydrogen, and oxygen and selected from the group consisting of polyesters, polycarbonates, polyethers, PC, PET, PMMA, etc., the polymer material containing carbon, hydrogen, oxygen, and nitrogen and selected from the group consisting of polyamines, polyimides, polyurethanes, PA, PI, PU, etc., the polymer material containing carbon, hydrogen, and nitrogen and selected from the group consisting of polyimines, phenol-and-amine-formaldehydes (polyethylene imine), etc., the polymer material containing carbon, hydrogen, oxygen, and sulfur and selected from the group consisting of polyester sulfone (polysulfones), PES, etc., the polymer material containing carbon, hydrogen, and fluorine and selected from the group consisting of polyvinylidene fluoride (PVDF), etc., the polymer material containing carbon and fluorine and selected from the group consisting of PTFE, Teflon, etc., the polymer material containing carbon, hydrogen, and chlorine and selected from the group consisting of polyvinyl chloride, polyvinylidene chloride (PVDC), etc., or the polymer material containing carbon, hydrogen, oxygen, and silicon and selected from the group consisting of polydimethylsiloxane, polycarbonate-siloxane, or silicon rubber, etc.

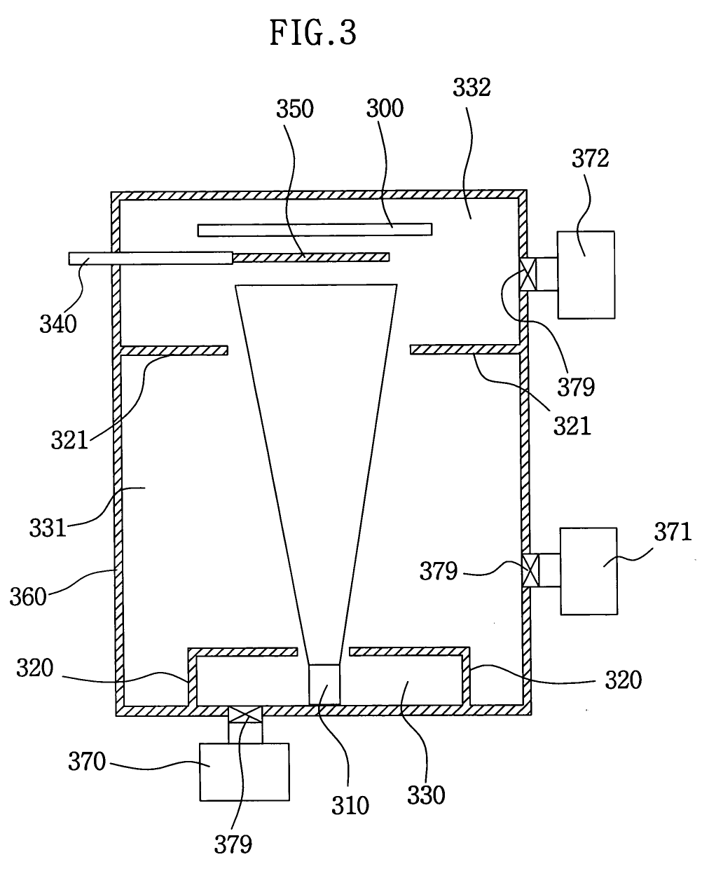

FIG. 3 schematically illustrates an apparatus for modifying a surface of a material using an ion beam according to a second embodiment of the present invention.

Referring to FIG. 3, an apparatus for modifying a surface of a material using an ion beam by controlling a partial pressure of a reactive gas is shown. The apparatus includes an ion gun 310 for surface modification in a vacuum chamber 360, a reactive gas inlet 340, a reactive gas distributor 350, partitioning walls 320 and 321 separating an inside of the vacuum chamber 360, vacuum pumps 370, 371, and 372 generating a vacuum inside the vacuum chamber 360, and exhaust valves 379 installed at front ends of the vacuum pumps 370, 371, and 372 to control a vacuum exhaust speed and an exhaust speed of a reactive gas.

A surface-modification substrate material 300 is positioned in an upper part of the vacuum chamber 360 facilitating a vacuum maintenance and a generation of an ion beam, and the ion gun 310 generating the ion beam is installed in a lower part of the vacuum chamber 360. And, the reactive gas distributor 350, which is connected to the reactive gas inlet 340 for supplying the reactive gas and uniformly maintains the partial pressure of the reactive gas over the entire surface of the surface-modification substrate material 300, is loaded thereon.

Installed in the vacuum chamber 360 are the first partitioning wall 320 separating a first area 330 around the ion gun 310 except a portion through which the ion beam passes and the second partitioning wall 321 separating a third area 332 around the surface-modification substrate material 300 from a second area 331 in the middle part of the vacuum chamber 360 except the portion through which the ion beam passes. And, the first to third vacuum pumps 370, 371, and 372 generating to maintain independent vacuums of the first to third areas 330 to 332, respectively are installed therein.

The reactive gas supplied from the gas distributor 350 is dispersed on a surface of the surface-modification substrate material 300, and a portion of the reactive gas supplied from the gas distributor 350 flows into the ion gun 310.

The reactive gas having flown into the ion gun 310 reacts with a filament (not shown in the drawing) inside the ion gun 310 to cause damage on the filament due to oxidation or nitridation and prevents a generation of plasma.

Hence, the first to third areas 330 to 332 having the independent vacuums in the vacuum chamber 360 respectively by installing the first and second partitioning walls 320 and 321 are separated from each other. Hence, when the reactive gas is injected around the surface-modification substrate material 300, the reactive gas has difficulty in diffusing into the first area 330 having the ion gun 310 located therein and it is easy to control the partial pressure of the reactive gas in the third area 332 having the surface-modification substrate material 300 located therein.

The third area 332, in which the surface-modification substrate material 300 is located, has a vacuum degree lower than that of the first area 330 having the ion gun 310 installed therein, whereby the reactive gas fails to flow in the first area 330 but is discharged outside in direct.

Moreover, the first and second partitioning walls 320 and 321 enable to expose a portion of the surface-modification substrate material 300 to be treated only to carry out a surface modification on a demanded portion selectively, thereby enabling to prevent particles such as the reactive gas and the like from being put into the ion gun 310.

It is also possible that the first to third vacuum pumps 370 to 371 having the different vacuum degrees respectively are installed to control the partial pressure between a surrounding of the surface-modification substrate material 300 and a surrounding of the ion gun 310 more effectively.

In order to prevent the case that a surface modification effect varies according to a location since the reactive gas fails to maintain a partial pressure uniformly on the surface of the surface-modification substrate material 300, the gas distributor 350 is connected to the reactive gas inlet 340 to maintain the partial pressure of the reactive gas on the entire surface of the surface-modification substrate material 300 uniformly. In FIG. 10 and FIG. 11, shown are the detailed description and layout of the gas distributor according to the second embodiment of the present invention and another detailed description and layout of the respective gas distributors having an ion beam current measuring device. Hence, it is able to improve an ion beam treatment effect and efficiency of the surface-modification substrate material using the gas distributors (some of them may have an ion beam current measuring device installed therein) properly and respectively. And, the corresponding shapes are exactly illustrated in FIG. 10 and FIG. 11.

The gas distributor 350 is separated from the surface-modification substrate material 300 to leave a predetermined interval in parallel from each other, and a hole (not shown in the drawing) through which the reactive gas is supplied is disposed to face the surface of the surface-modification substrate material 300.

The exhaust valves 379 are installed at the front ends of the vacuum pumps 370, 371, and 372 to control the vacuum exhaust speed and the exhaust speed of the reactive gas to maximize a time that the reactive gas stays around the surface-modification substrate material 300 and the partial gas pressure of the reactive gas. Thus, the exhaust valves 279 maximize a reaction between the surface-modification substrate material 300 having the ion beam irradiated thereon and the reactive gas, thereby enabling to improve the ion beam treatment effect and efficiency thereof.

The surface-modification substrate material 300 is a material including a metal, ceramic, or a polymer material, and may have a curved surface. And, the organic material uses a polymer material combined with a material such as carbon, oxygen, nitrogen, fluorine, silicon, and the like.

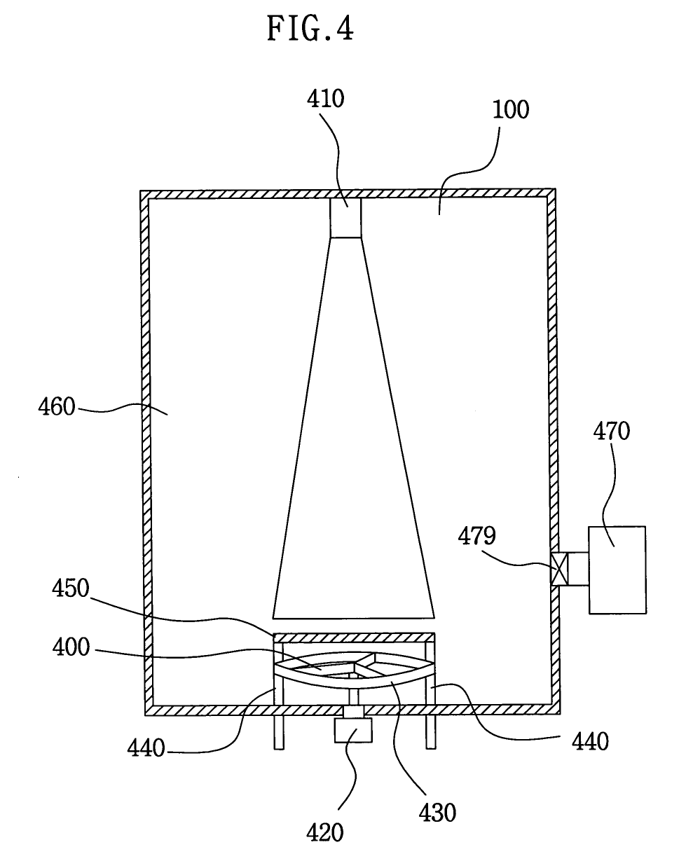

FIG. 4 schematically illustrates an apparatus for modifying a surface of a material using an ion beam according to a third embodiment of the present invention.

Referring to FIG. 4, an apparatus for modifying a surface of a material using an ion beam is shown in case that a surface-modification substrate material 400 is a powder. The apparatus includes an ion gun 410 for surface modification in a vacuum chamber 460, a holder 430 agitating the surface-modification substrate material 400, a reactive gas inlet 440, a reactive gas distributor 450, a vacuum pumps 470, generating a vacuum inside the vacuum chamber 460, and an exhaust valve 479 installed at a front end of the vacuum pump 470 to control a vacuum exhaust speed and an exhaust speed of a reactive gas.

The ion gun 410 generating an ion beam is installed in an upper part of the vacuum chamber 460 to facilitate a vacuum maintenance and a generation of the ion beam, and the holder 430 driven by a motor 420 and supporting to agitate the surface-modification substrate material 400 of the powder is located in a lower part of the vacuum chamber 460.

In a periphery of the holder 430 installed are the reactive gas inlets 440 penetrating a bottom of the vacuum chamber 460 to supply the reactive gas, the gas distributor 450 connected to the reactive gas inlets 440 to maintain the reactive gas on the entire surface-modification substrate material 400 uniformly, the vacuum pump 470 generating a vacuum of the vacuum chamber 460, and the exhaust valve 479 installed at a front end of the vacuum pump 470 to control a vacuum exhaust speed and an exhaust speed of the reactive gas.

In the first or second embodiment of the present invention, the ion gun is installed in the lower part of the vacuum chamber and the surface-modification substrate material is disposed in the upper part of the vacuum chamber to fabricate a film on the surface of the surface-modification substrate material.

Namely, the apparatus has a constitution that a target is installed at a side opposite to the ion gun like an ion beam sputter. Yet, the surface-modification substrate material 400, as shown in FIG. 4, having the powder or nonuniform shape is unable to be held in the upper part of the vacuum chamber 460. Hence, the ion gun 410 and the holder 430 are installed in the upper and lower parts of the vacuum chamber 460, respectively, the surface-modification substrate material of the powder phase is loaded on the holder, and the surface-modification substrate material 400 is agitated to carry out the surface modification.

Besides, in case of injecting the reactive gas, the reactive gas inlets 440 are installed around the surface-modification substrate material 400 of the powder phase or inside the holder 430 to control an amount of the reactive gas.

In order to prevent the case that a surface modification effect varies according to a location since the reactive gas fails to maintain a partial pressure uniformly on the surface of the surface-modification substrate material 400, the gas distributor 450 is connected to the reactive gas inlets 440 to maintain the partial pressure of the reactive gas on the entire surface of the surface-modification substrate material 400 uniformly. In FIG. 10 and FIG. 11, shown are the detailed description and layout of the gas distributor according to the third embodiment of the present invention and another detailed description and layout of the respective gas distributors having an ion beam current measuring device. Hence, it is able to improve an ion beam treatment effect and efficiency of the surface-modification substrate material using the gas distributors (some of them may have an ion beam current measuring device installed therein) properly and respectively. And, the corresponding shapes are exactly illustrated in FIG. 10 and FIG. 11.

The gas distributor 450 is separated from the surface-modification substrate material 400 to leave a predetermined interval in parallel from each other, and a hole (not shown in the drawing) through which the reactive gas is supplied is disposed to face the surface of the surface-modification substrate material 400.

The exhaust valve 479 is installed at the front end of the vacuum pump 470 to control the vacuum exhaust speed and the exhaust speed of the reactive gas to maximize a time that the reactive gas stays around the surface-modification substrate material 400 and the partial gas pressure of the reactive gas. Thus, the exhaust valve 479 maximizes a reaction between the surface-modification substrate material 400 having the ion beam irradiated thereon and the reactive gas, thereby enabling to improve the ion beam treatment effect and efficiency thereof.

The surface-modification substrate material 400 of the powder phase is an organic material including a metal film, ceramic film, or a polymer material, and may have a curved surface. And, the organic material uses a polymer material combined with a material such as carbon, oxygen, nitrogen, fluorine, silicon, and the like.

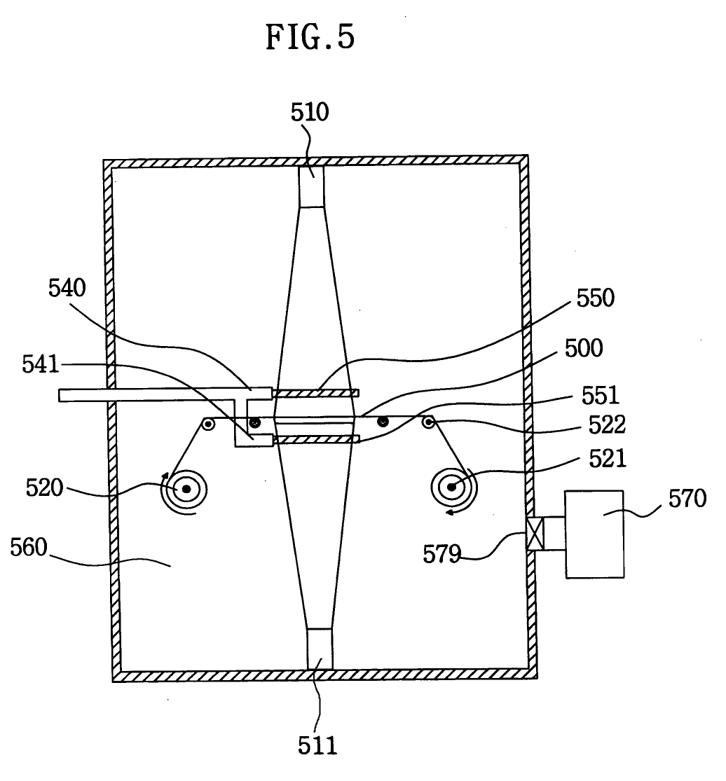

FIG. 5 schematically illustrates an apparatus for modifying a surface of a material using an ion beam according to a fourth embodiment of the present invention.

Referring to FIG. 5, an apparatus for modifying a surface of a material using a plurality of ion beams treating both sides of a surface-modification substrate material 500 is shown. The apparatus includes rollers 520, 521, and 522 for supplying/discharging a surface-modification substrate material 500 in the middle of a vacuum chamber 560, ion guns 510 and 511 in upper and lower parts of the vacuum chamber 560, reactive gas inlets 540 and 541 over and under the surface-modification substrate material 500, respectively, gas distributors 550 and 551 over and under the surface-modification substrate material 500, respectively, a vacuum pump 570 generating a vacuum inside the vacuum chamber 560, and an exhaust valve 579 installed at a front end of the vacuum pump 570 to control a vacuum exhaust speed and an exhaust speed of a reactive gas.

Inside the vacuum chamber 560 to facilitate a vacuum maintenance and a generation of the ion beams, installed are the supply roller 520 having a long length and front and rear faces to supply the surface-modification substrate material 500 having a film shape, the guide rollers 522 normally transferring the surface-modification substrate material 500 to an ion beam treatment area and the take-up roller 521, and the take-up roller 521 winding back the surface-modified surface-modification substrate material 500.

In order to carry out a surface modification on the surface-modification substrate material 500 having the front and rear faces, the first and second ion guns 510 and 511 generating the ion beams are installed in the upper and lower parts of the vacuum chamber 560, respectively.

The first and second reactive gas inlets 540 and 541 entering the vacuum chamber 560 are installed near the front and rear faces of the surface-modification substrate material 500 to supply the reactive gas, respectively. In order to maintain a partial pressure of the reactive gas on the front and rear faces of the surface-modification substrate material 500 uniformly, the first and second gas distributors 550 and 551 are connected to the first and second reactive gas inlets 540 and 541, respectively. And, the vacuum pump 570 generating the vacuum of the vacuum chamber 560 and the exhaust valve 579 installed at the front end of the vacuum pump 570 to control a vacuum exhaust speed and an exhaust speed of the reactive gas are installed.

In order to modify the front and rear faces of the surface-modification substrate material 500, the first and second ion guns 510 and 511 are installed in the upper and lower parts of the vacuum chamber 560 to confront each other, and the ion beams are applied to the front and rear faces of the surface-modification substrate material 500 to carry out the surface modification thereon. In this case, if the surface-modification substrate material 500 has at least three faces, at least three ion guns can be installed to apply the ion beams to the corresponding faces, respectively.

As the first and second ion guns 510 and 511 enable to apply the ion beams to the front and rear faces of the surface-modification substrate material 500 by 45°, 60°, and 90°, it is able to carry out uniformly the surface modification on the surface-modification substrate material 500 having various shapes such as sphere, curve, and the like.

In the fourth embodiment of the present invention, the surface-modification substrate material 500 such as fiber, film, and the like having front and rear faces is suitable for the surface modification. For mass production, the surface-modification substrate material 500 is made to have the shape such as foil, sheet, and the like to carry out the surface modification continuously thereon.

In order to carry out the surface modification on the surface-modification substrate material 500 having the film, foil, or sheet shape continuously, installed are the supply roller 520 supplying the surface-modification substrate material 500 inside the vacuum chamber 560, the take-up roller 521 winding back the surface-modified surface-modification substrate material 500, the guide rollers 522 normally transferring the surface-modification substrate material 500 from the supply roller 520 to the take-up roller 521 through an ion beam treatment area, and a device (not shown in the drawing) for adjusting a supply speed or a tension of the surface-modification substrate material 500.

In order to prevent the case that a surface modification effect varies according to a location since the reactive gas fails to maintain a partial pressure uniformly on the surface of the surface-modification substrate material 500, the first and second gas distributors 550 and 551 are connected to the first and second reactive gas inlets 540 and 541, respectively to maintain the partial pressure of the reactive gas on the entire surface of the surface-modification substrate material 500 uniformly. In FIG. 10 and FIG. 11, shown are the detailed description and layout of the gas distributors according to the fourth embodiment of the present invention and another detailed description and layout of the respective gas distributors having the ion beam current measuring device. Hence, it is able to improve an ion beam treatment effect and efficiency of the surface-modification substrate material using the gas distributors (some of them may have an ion beam current measuring device installed therein) properly and respectively. And, the corresponding shapes are exactly illustrated in FIG. 10 and FIG. 11.

The first and second gas distributor 550 and 551 are separated from the front and rear faces of the surface-modification substrate material 500 to leave predetermined intervals in parallel from each other, respectively and holes (not shown in the drawing) through which the reactive gas is supplied are disposed to face the surfaces, i.e. front and rear faces, of the surface-modification substrate material 500.

The surface-modification substrate material 500 is an organic material including a metal film, ceramic film, or a polymer material, and may have a curved surface. And, the organic material uses a polymer material combined with a material such as carbon, oxygen, nitrogen, fluorine, silicon, and the like.

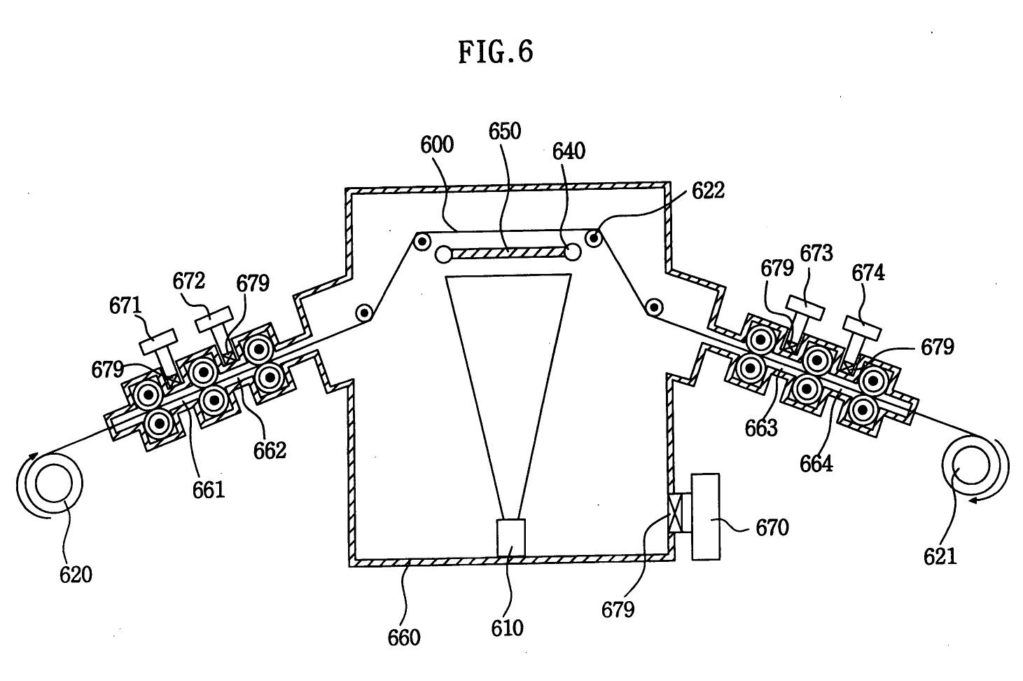

FIG. 6 schematically illustrates an apparatus for modifying a surface of a material using an ion beam according to a fifth embodiment of the present invention.

Referring to FIG. 6, an apparatus for modifying a surface of a material using an ion beam enables a continuous process by putting a surface-modification substrate material 600 in a vacuum chamber from an atmospheric environment. The apparatus includes auxiliary vacuum chambers 661, 662, 663, and 664 providing a vacuum required for supplying a surface-modification material 600 inside a main vacuum chamber 660, which is an ion beam treatment area, from an atmospheric environment or discharging the surface-modification substrate material 600 outside the main vacuum chamber 660, rollers 620, 621, and 622 transferring the surface-modification substrate material 600, an ion gun 610 in a lower part of the main vacuum chamber 660, reactive gas inlets 640 installed nearby under the surface-modification substrate material 600, a gas distributor 650 installed nearby under the surface-modification substrate material 600, vacuum pumps 670, 671, 672, 673, and 674 generating vacuums inside the main vacuum chamber 660 and the auxiliary vacuum chambers 661, 662, 663, and 664, respectively, and exhaust valves 679 installed at front ends of the vacuum pumps 670, 671, 672, 673, and 674 to control a vacuum exhaust speed and an exhaust speed of a reactive gas, respectively.

When the surface-modification substrate material 600 having a film shape in the atmosphere is supplied into the main vacuum chamber 660 as the ion beam treatment area, the first and second vacuum chambers 661 and 662 as the auxiliary vacuum chambers generating high vacuums sequentially are required for attaining a high vacuum necessary for the main vacuum chamber 660 from a low vacuum.

A first vacuum is formed in the first vacuum chamber 661, a vacuum higher than the first vacuum is attained in the second vacuum chamber 662, and the vacuum necessary for ion beam treatment is provided in the main vacuum chamber 660 to carry out surface modification. In this case, the first vacuum chamber 661 generating the first vacuum is provided for forming a first vacuum state and demands no large volume. If the first vacuum is insufficient, the second vacuum chamber 662 is installed therein to attain a necessary vacuum. Moreover, at least another two auxiliary vacuum chambers can be further installed to attain a high vacuum. Namely, at least one auxiliary vacuum chamber for providing a high vacuum can be installed therein.

The third and fourth vacuum chambers 663 and 664 are required for attaining a low vacuum in a manner reverse to the sequence required for attaining the necessary vacuum state when the surface-modified surface-modification substrate material 600 is discharged into the atmosphere outside the main vacuum chamber 660 as the ion beam treatment area.

A third vacuum lower than that of the main vacuum chamber 660 is attained in the third vacuum chamber 663, and a vacuum lower than the third vacuum is provided in the fourth vacuum chamber 664. The surface-modification substrate material 600 is then discharged into the atmosphere. If necessary, at least one auxiliary vacuum chamber for forming a low vacuum can be installed therein.

In a sequence reverse to that for attaining the demanded vacuum state, the surface-modified surface-modification substrate material 600 is discharged through the third vacuum chamber 663 forming a vacuum lower than that of the main vacuum chamber 660 by the third vacuum pump 673 and the fourth vacuum chamber 674 forming a vacuum lower than that of the third vacuum chamber 663 by the fourth vacuum pump 674. And, at least one vacuum chamber can be further installed therein to attain a vacuum lower than the previous vacuum.

And, the main vacuum pump 670, the first vacuum pump 671, the second vacuum pump 672, the third vacuum pump 673, and the fourth vacuum pump 674 are installed to generate the independent vacuums of the main vacuum chamber 660, the first vacuum chamber 661, the second vacuum chamber 662, the third vacuum chamber 663, and the fourth vacuum chamber 664, respectively.

A conveyer of the surface-modification substrate material 600 includes the supply roller 620 supplying the surface-modification substrate material 600 from the atmosphere, the take-up roller winding back the surface-modified surface-modification substrate material 600 in the atmosphere, the guide roller 622 normally transferring the surface-modification substrate material 600 to the take-up roller 621 from the supply roller 620 through the first vacuum chamber 661, the second vacuum chamber 662, the main vacuum chamber 660 as the ion beam treatment area, the third vacuum chamber 663, and the fourth vacuum chamber 664, and a device (not shown in the drawing) for controlling a supply speed or tension of the surface-modification substrate material 600.

The ion gun 610 is installed in a lower or upper part of the main vacuum chamber 660, and the surface-modification substrate material 600 of a film shape is disposed in the upper part of the main vacuum chamber 660. And, the gas distributor 650 is connected to the reactive gas inlet 640 injecting the reactive gas between the surface-modification substrate material 600 and the ion gun 610 to maintain a partial pressure of the reactive gas uniformly on the entire surface-modification substrate material 600.

In order to prevent the case that a surface modification effect varies according to a location since the reactive gas fails to maintain a partial pressure uniformly on the surface of the surface-modification substrate material 600, the gas distributor 650 is connected to the reactive gas inlets 640 to maintain the partial pressure of the reactive gas on the entire surface of the surface-modification substrate material 600 uniformly. In FIG. 10 and FIG. 11, shown are the detailed description and layout of the gas distributor according to the fifth embodiment of the present invention and another detailed description and layout of the respective gas distributors having an ion beam current measuring device. Hence, it is able to improve an ion beam treatment effect and efficiency of the surface-modification substrate material using the gas distributors (some of them may have an ion beam current measuring device installed therein) properly and respectively. And, the corresponding shapes are exactly illustrated in FIG. 10 and FIG. 11.

The gas distributor 650 is separated from the surface-modification substrate material 600 to leave a predetermined interval in parallel from each other, and a hole through which the reactive gas is supplied is disposed to face the surface of the surface-modification substrate material 600.

The exhaust valves 679 are installed at the front ends of the vacuum pumps 670 to 674 to control the vacuum exhaust speed and the exhaust speed of the reactive gas to maximize a time that the reactive gas stays around the surface-modification substrate material 600 and the partial gas pressure of the reactive gas. Thus, the exhaust valves 679 maximize a reaction between the surface-modification substrate material 600 having the ion beam irradiated thereon and the reactive gas, thereby enabling to improve the ion beam treatment effect and efficiency thereof.

The surface-modification substrate material 600 is an organic material including a metal film, ceramic film, or a polymer material, and may have a curved surface. And, the organic material uses a polymer material combined with a material such as carbon, oxygen, nitrogen, fluorine, silicon, and the like.

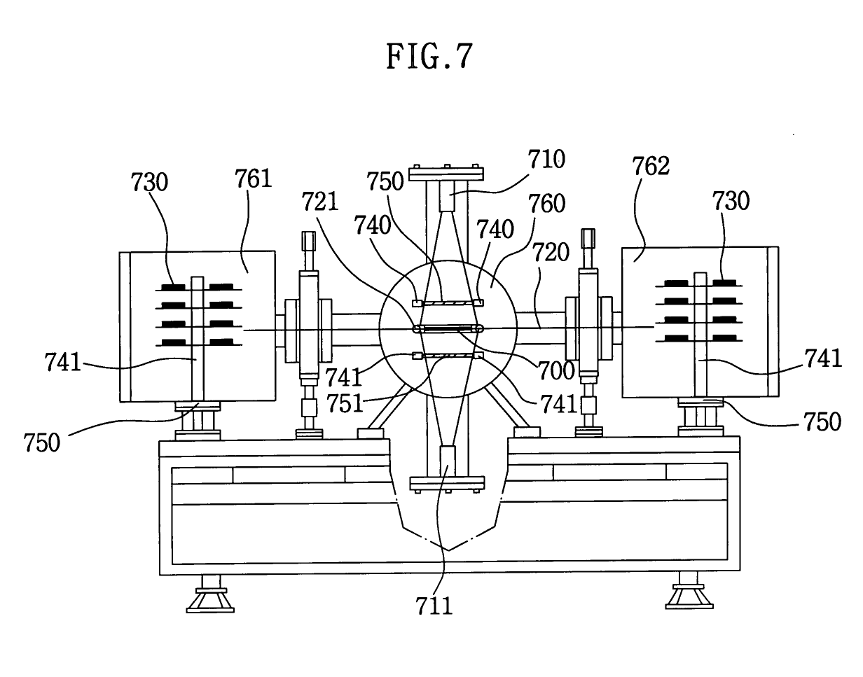

FIG. 7 schematically illustrates an apparatus for modifying a surface of a material using an ion beam according to a sixth embodiment of the present invention.

Referring to FIG. 7, an apparatus for modifying a surface of a material using an ion beam enabling to treat a plate-like material is shown. The apparatus includes auxiliary vacuum chambers 761 and 762 loading or unloading a surface-modification substrate material 700 in or from a main vacuum chamber 760, a belt conveyer system 720 transferring the surface-modification substrate material 700, ion guns 710 and 711 installed in upper and lower parts of the main vacuum chamber 760 to generate ion beams, respectively, reactive gas inlets 740 and 741 and gas distributors 750 and 751 installed between the surface-modification substrate material 700 and the ion guns 710 and 711 of the main vacuum chamber 760, vacuum pumps (not shown in the drawing) generating vacuums inside the main vacuum chamber 760 and the auxiliary vacuum chambers 761 and 762, respectively, and exhaust valves (not shown in the drawing) installed at front ends of the vacuum pumps respectively to control a vacuum exhaust speed and an exhaust speed of a reactive gas.

The first and second ion guns 710 and 711 are installed in the upper and lower parts of the main vacuum chamber 760 to generate the ion beams, respectively and the surface-modification substrate material 700 is disposed at a support holder 721 to expose both front and rear faces of the plate-like surface-modification substrate material 700.

The first and second reactive gas inlets 740 and 741 are installed between the front face of the support holder 721 and the first ion gun 710 and between the rear face of the support holder 721 and the second ion gun 711, respectively to supply the reactive gas. In order to maintain a partial pressure of the reactive gas on the entire surface-modification substrate material 700 uniformly, the first and second gas distributors 750 and 751 are connected to the first and second reactive gas inlets 740 and 741, respectively.

The first auxiliary vacuum chamber 761 for making the surface-modification substrate material 700 stand by or supplying the surface-modification substrate material 700 into the main vacuum chamber 760 is installed at one side of the main vacuum chamber 760 facilitating a vacuum maintenance and a generation of the ion beams, and the second auxiliary vacuum chamber 762 unloading the ion-beam-treated surface-modification substrate material 700 from the main vacuum chamber 760 as an ion beam treatment area is installed at the other side of the main vacuum chamber 760.

In each of the first and second auxiliary vacuum chambers 761 and 762, installed are a vertically movable rod 741 supporting a holder to move upward and downward and a holder 730 receiving a plurality of the surface-modification substrate materials 700 therein. The holder 739 revolves to be connected to the belt conveyer system 720 to load/unload the surface-modification substrate material 700 in/from the main vacuum chamber 760. And, a holder revolving system 750 driven by a stepping motor to have an angular rotation is installed under each of the first and second auxiliary vacuum chambers 761 and 762.

In order to transfer the plate-like surface-modification substrate material 700, the belt conveyer system 720 traverses the main vacuum chamber 760 from the first auxiliary vacuum chamber 761 to extend to the second auxiliary vacuum chamber 762.

A main vacuum pump (not shown in the drawing), a first vacuum pump (not shown in the drawing), and a second vacuum pump (not shown in the drawing) are installed to generate the independent vacuums in the main vacuum vessel 760, the first auxiliary vacuum chamber 761, and the second auxiliary vacuum chamber 762, respectively.

FIG. 7 shows the ion beam treatment apparatus enabling to continuously treat the plate-like surface-modification substrate material 700 having a certain mechanical strength, and the plate-like surface-modification substrate material 700 is such a material having a certain strength as a silicon wafer, a metal plate, and a ceramic thick film.

In order to prevent the case that a surface modification effect varies according to a location since the reactive gas fails to maintain a partial pressure uniformly on the surface of the surface-modification substrate material 700, the first and second gas distributors 750 and 751 are connected to the first and second reactive gas inlets 740 and 741 to maintain the partial pressure of the reactive gas on the entire surface of the surface-modification substrate material 700 uniformly. In FIG. 10 and FIG. 11, shown are the detailed description and layout of the gas distributor according to the sixth embodiment of the present invention and another detailed description and layout of the respective gas distributors having an ion beam current measuring device. Hence, it is able to improve an ion beam treatment effect and efficiency of the surface-modification substrate material using the gas distributors (some of them may have an ion beam current measuring device installed therein) properly and respectively. And, the corresponding shapes are exactly illustrated in FIG. 10 and FIG. 11.

The first and second gas distributors 750 and 751 are separated from front and rear faces of the surface-modification substrate material 700, respectively to leave a predetermined interval in parallel from each other, and a hole through which the reactive gas is supplied is disposed to face the surface of the surface-modification substrate material 700.

The exhaust valves (not shown in the drawing) are installed at the front ends of the vacuum pumps to control the vacuum exhaust speed and the exhaust speed of the reactive gas to maximize a time that the reactive gas stays around the surface-modification substrate material 700 and the partial gas pressure of the reactive gas. Thus, the exhaust valves maximize a reaction between the surface-modification substrate material 700 having the ion beam irradiated thereon and the reactive gas, thereby enabling to improve the ion beam treatment effect and efficiency thereof.

The surface-modification substrate material 700 is an organic material including a metal film, ceramic film, or a polymer material, and may have a curved surface. And, the organic material uses a polymer material combined with a material such as carbon, oxygen, nitrogen, fluorine, silicon, and the like.

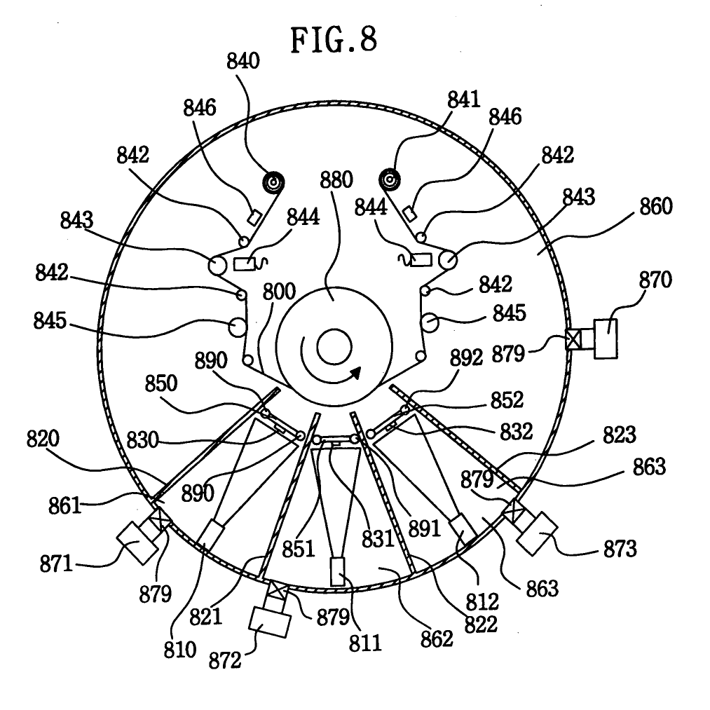

FIG. 8 schematically illustrates an apparatus for modifying a surface of a material using an ion beam according to a seventh embodiment of the present invention.

Referring to FIG. 8, an apparatus for modifying a surface of a material using ions beams of ion beam treatment areas 861 to 863 modifies a surface of a surface-modification substrate material 800 by installing a plurality of the ion beam treatment areas 861 to 863 and transfers the surface-modification substrate material 800 of a film shape to the ion beam treatment areas 861 to 863 using a drum 880. The apparatus includes a plurality of ion beam treatment areas 861 to 863 separated by partitioning walls 820 to 823, respectively centering around a drum of a vacuum chamber 860, a drum 880 and rollers 840 to 845 for transferring a surface-modification substrate material 800 to the ion beam treatment areas 861 to 863, ion guns 810 to 812 in lower parts of the ion beam treatment areas 861 to 863, reactive gas inlets 890 to 892 and gas distributors 850 to 852 between the drum 880 and the ion guns 810 to 812 in a plurality of the ion beam treatment areas 861 to 863, vacuum pumps 870 to 873 installed to maintain independent vacuums of the vacuum chamber 860 and a plurality of the ion beam treatment areas 861 to 863, respectively, and exhaust valves 879 installed at front ends of the vacuum pumps 870 to 873 to control a vacuum exhaust speed and an exhaust speed of the reactive gas.

The drum 880 is installed at a center of the vacuum chamber 860 to revolve by a motor (not shown in the drawing) to transfer the surface-modification substrate material 800 of a film shape, and the first to fourth partitioning walls 820 to 823, which maintain the independent vacuums between the drum 880 and inner walls of the vacuum chamber 860, respectively and prevent a mixed loading of the reactive gas, are installed to partition the vacuum chamber 860.

A space between the first and second partitioning walls 820 and 821 in the vacuum chamber 860 is the first ion beam treatment area 861, a space between the second and third partitioning walls 821 and 822 is the second ion beam treatment area 862, a space between the third and fourth partitioning walls 822 and 823 is the third ion beam treatment area 863, and a space between the first and fourth partitioning walls 820 and 823 is a roller installing area.

The first to third and main vacuum pumps 871 to 873 and 870 are installed to maintain the independent vacuums of the first to third ion beam treatment areas 861 to 863 and the vacuum chamber 860, respectively.

A conveyer transferring the surface-modification substrate material 800 is installed in the roller installing area 864, and includes a supply spool 840, a take-up spool 841, guide rollers 842, dance rollers 843, proximity switches 844, spreader rollers 845, and static eliminators 846.

In this case, the supply spool 840 is installed to supply the first to third ion beam treatment areas 861 to 863 with the surface-modification substrate material 800 for surface modification, and the take-up spool 841 has a function of winding back the surface-modification substrate material 800 having been surface-modified in the first to third ion beam treatment areas 861 to 863.

The guide rollers 842 guide the surface-modification substrate material 800 to be normally transferred to the take-up spool 841 from the supply spool 840 through the drum 880, and the dance rollers 843 control a tension applied to the surface-modification substrate material 800. And, the proximity switches control the dance rollers 843, respectively.

The spreader rollers 845 prevent the surface-modification substrate material 800 between the guide rollers 842 from being wrinkled. The static eliminators 846 are installed between the supply spool 840 and the guide roller 842 and between the take-up spool 841 and the other guide roller 842, and play a role of removing static electricity generated from a friction of the surface-modification substrate material 800 or an ion beam surface modification.

The first to third ion guns 810 to 812 are installed in lower parts of the first to third ion beam treatment areas 861 to 863 centering around the drum 880, respectively.

The ion guns used for the surface modification of the surface-modification substrate material 800 may be selected from the group consisting of a Kaufman ion gun using a filament method, a cold hollow cathode ion gun using a cold cathode ray tube, a radio frequency (RF) ion gun using a radio frequency, a high frequency (HF) ion gun using a high frequency, and the like.

The first to third reactive gas inlets 890 to 892 are installed between the drum 880 and the first to third ion guns 810 to 812 in the first to third ion beam treatment areas 861 to 863 to supply the reactive gas thereto, respectively. In order to maintain a gas pressure on the entire surface-modification substrate material 800 uniformly, the first to third gas distributors 850 to 852 are connected to the first to third reactive gas inlets 890 to 892, respectively.

First to third ion beam current measuring devices 830 to 832 are installed in the first to third ion beam treatment areas 861 to 862 near the drum 880 to measure ion beam currents, respectively.

The main vacuum pump 870 and the first to third vacuum pumps 871 to 873 are installed to maintain independently the vacuums of the vacuum chamber 860 and the first to third ion beam treatment areas 861 to 863, respectively.

The exhaust valves 879 are installed at the front ends of the vacuum pumps 870 to 873, respectively to improve an ion beam treatment effect and efficiency by maximizing a reaction between the reactive gas and the ion-beam-applied surface-modification substrate material 800 by controlling the vacuum exhaust speed and the exhaust speed of the reactive gas to maximize the partial pressure of the reactive gas and the time that the reactive gas stays around the surface-modification substrate material 800.

The surface-modification substrate material 800 is made of polymer, ceramic, or metal, and has a film or foil shape having a long length.

In order to prevent a mixed loading of the reactive gas for generating the ion beams, the first to third ion beam treatment areas 861 to 863 are installed using the first to fourth partitioning walls 820 to 823, And, the surface modification is carried out on the surface-modification substrate material 800 in the three ion beam treatment areas independently and simultaneously.

The drum 880 adjacent to the first to third ion beam treatment areas 861 to 863 enables to operate at a temperature range of −(minus)100° C.˜300° C.

In case of cooling the drum 880, it is able to prevent the surface-modification substrate material 800 having a low glass temperature or a low melting point from being damaged by a heat generated from the ion beam treatment. In case of heating the drum 880, it is able to maximize the ion beam treatment effect for the surface-modification substrate material 800 having a strong thermal resistance.

The static eliminators between the supply spool 840 and the guide roller 842 and between the take-up spool 841 and the other guide roller 842 remove the static electricity generated from the friction of the surface-modification substrate material 800 and the ion beam treatment. When the static electricity exists on a surface of the surface-modification substrate material 800, the surface-modification substrate material 800 having been irregularly surface-modified by a charging or spark of the ion beam generates the static electricity after being wound back. Hence, it is difficult to protect a user from the static electricity safely.

When the ion beam surface treatment is carried out by generating the same kind of ion beams from the first to third ion guns 810 to 812 and injecting the same kind of the reactive gas through the first to third gas distributors 850 to 852, the surface modification time of the surface-modification substrate material 800 is reduced to achieve a fast process.

Moreover, when the ion beam surface treatment is carried out by generating the different kinds of ion beams from the first to third ion guns 810 to 812 and injecting the different kinds of the reactive gases through the first to third gas distributors 850 to 852, respectively, a different functional group of the surface-modification substrate material 800 is formed to provide various effects of a single surface modification.

In order to prevent the case that the surface modification effect is changed according to a location since the partial pressure fails to be maintained uniformly on the surface-modification substrate material 800, the first to third gas distributors 850 to 852, as shown in FIG. 10 and FIG. 11, are installed to uniformly maintain the partial pressures of the reactive gas supplied to the first to third ion beam treatment areas 861 to 863 on the entire surface-modification substrate material 800.

Each of the first to third gas distributors 850 to 852 is separated from the surface-modification substrate material 800 to leave a predetermined interval in parallel from each other, and holes through which the reactive gas is supplied are disposed to face the surface of the surface-modification substrate material 800.

The surface-modification substrate material 800 is a material including a metal, ceramic, or a polymer material, and may have a curved surface. And, the organic material uses a polymer material combined with a material such as carbon, oxygen, nitrogen, fluorine, silicon, and the like.

Explained in the following is an example for carrying out an ion beam surface treatment by generating the different kinds of the ion beams from the first to third ion guns 810 to 812 and injecting the different kinds of the reactive gases through the first to third gas distributors 850 to 852.

First of all, the first to third ion guns 810 to 812 around the drum 880 are the cold hollow cathode type and Ar and H₂ are injected to use.

Oxygen (O₂) and/or ammonia (NH₃) as the reactive gas are supplied through the first to third reactive gas inlets 890 to 892 to form an reaction ambience, and the surface-modification substrate material 800 is a polyethylene (PE) film of 25 μm thickness.

Ar is supplied to the first and second ion guns 810 and 811 to generate Ar ions, and hydrogen is supplied to the third ion gun 812 to generate hydrogen ions.

An Ar gas for the first ion gun 810 is injected in the first ion beam treatment area 861 instead of the reactive gas, an oxygen gas as the reactive gas is injected in the second ion beam treatment area 862 using the second reactive gas inlet 891 and the second gas distributor 851, and an ammonia gas as the reactive gas is injected in the third ion beam treatment area 863 using the third reactive gas inlet 892 and the third gas distributor 852.

The reactive gases injected in the first to third ion beam treatment areas 861 to 863 enable to exist in the corresponding ion beam treatment areas, respectively, without being mixed with each other, due to the first to third vacuum pumps 971 to 873 independently forming the vacuums with the first to fourth partitioning walls 820 to 823.

The surface-modification substrate material 800 is supplied by the supply spool 840, and passes the first to third ion beam treatment areas 861 to 863 by the drum 880 through the guide rollers 842, dance rollers 843, and spreader rollers 845.

Ar ions are generated by the first ion gun 810 in the first ion beam treatment area 861, and the ions accelerated by a voltage of 1.5 KV are irradiated on the surface-modification substrate material 800 of polyethylene. The Ar ions collide with a surface of polyethylene, whereby unstable polymer chains are formed by the energized ion collision.

The unstable polymer chains bring about cross-linking to form a stable huge polymer chain on the surface of polyethylene, thereby enabling to prevent a flowing of the polymer chains.

The polyethylene film having passed the first ion beam treatment area 861 reaches the second ion beam treatment area 862, a voltage of 1 KV is applied to the second ion gun 811 to generate Ar ions, and oxygen as the reactive gas is supplied through the second reactive gas inlet 891 and the second gas distributor 851.

An amount of the reactive gas varies in accordance with a vacuum degree and a process condition, and generally lies within a range of 0˜500 sccm. And, a working pressure maintains 10⁻¹˜10⁻⁵ torr.

Functional groups such as carboxyl [—(C═O)—O—], ester [—(C═O)—], ether [—(C—O)—], and the like are formed on the surface of polyethylene by the irradiated Ar ion beam thereon and the oxygen gas. Such a functional group gives the polyethylene surface a hydrophilic property and an adhesion.

Moreover, the hydrogen ions are generated from the third ion beam treatment area 863 by supplying the third ion gun 812 with a hydrogen gas, and an ammonia gas is supplied through the third reactive gas inlet 892 and the third gas distributor 852.

An amount of the reactive gas varies in accordance with a vacuum degree and a process condition, and generally lies within a range of 0˜500 sccm. And, a working pressure maintains 10⁻¹˜10⁻⁵ torr.

In case of using the hydrogen ions and the ammonia gas, a functional group of amine ‘(NHₓ)’ is formed on the polyethylene surface, and such a functional group improves the hydrophilic property and adhesion of the polyethylene surface as well.

The cross-linking formed on the polyethylene surface in the first ion beam treatment area 861 contributes to the stability of the functional group formed in the second and third ion beam treatment areas 862 and 863 thereafter.

Generally, a polymer chain has a low glass temperature enabling to flow at the room temperature. Even if the functional group is formed on the surface, the hydrophilic property and the adhesion are gradually reduced as time goes by since the functional group moves inside the polymer.

On the other hand, when the cross-linking is formed between polymer chains, a huge polymer is formed to prevent the flow of the polymer chain. And the functional group is kept on the surface to have a stability even if the time goes by. Moreover, it is able to form various functional groups on the polymer surface with a single process by varying the ion applied to polyethylene and the reactive gas in each of the ion beam treatment areas. Hence, it is able to form a surface having an excellent hydrophilic property and an excellent adhesion to various materials.

In addition to the above-explained example, the number of ion guns installed in the vacuum chamber, the species of the gas for generating ions, and the species of the reactive gas can be varied in accordance with purposes to enable the surface modifications of various films.

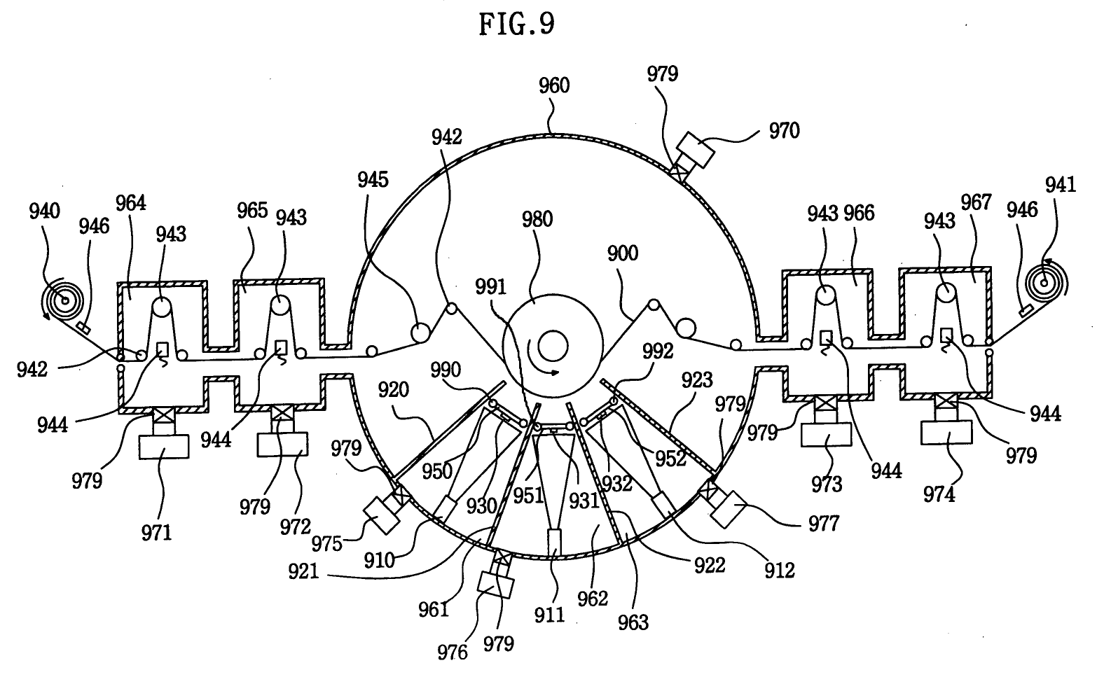

FIG. 9 schematically illustrates an apparatus for modifying a surface of a material using an ion beam according to an eighth embodiment of the present invention.

Referring to FIG. 9, an apparatus for modifying a surface of a material using ions beams having a drum 980 enables a continuous process by putting a surface-modification substrate material 900 inside a vacuum chamber from an atmospheric ambience. The apparatus includes a plurality of auxiliary vacuum chambers 964 to 967 for attaining vacuums necessary for supplying a surface-modification substrate material 900 into a main vacuum chamber 960 having a plurality of ion beam treatment areas 961 to 963 installed therein or discharging the surface-modification substrate material 900 outside the main vacuum chamber 960, a plurality of rollers 940, 941, 942, 943, and 945 for transferring the surface-modification substrate material 900, a plurality of ion guns 910 to 912 in lower parts of the ion beam treatment areas 961 to 963, reactive gas inlets 990 to 992 and gas distributors 950 to 952 between the drum 980 and the ion guns 910 to 912 in the ion beam treatment areas 961 to 963, respectively, vacuum pumps 970 to 976 installed to maintain independent vacuums of the main vacuum chamber 960 and the ion beam treatment areas 961 to 963, respectively, and exhaust valves 979 installed at front ends of the vacuum pumps 970 to 976 to control a vacuum exhaust speed and an exhaust speed of the reactive gas.

When the surface-modification substrate material 900 having a film shape in the atmosphere is supplied into the main vacuum chamber 960 having a plurality of the ion beam treatment areas installed therein, the first and second vacuum chambers 964 and 965 as the auxiliary vacuum chambers generating high vacuums sequentially are required for attaining a high vacuum necessary for the main vacuum chamber 960 from a low vacuum.

A first vacuum is formed in the first vacuum chamber 964, a vacuum higher than the first vacuum is attained in the second vacuum chamber 965, and the vacuum necessary for ion beam treatment is provided in the main vacuum chamber 960 to carry out a surface modification. In this case, the first vacuum chamber 964 generating the first vacuum is provided for forming a first vacuum state and demands no large volume. If the first vacuum is insufficient, the second vacuum chamber 965 is installed therein to attain a necessary vacuum with ease.

Moreover, at least another two auxiliary vacuum chambers can be further installed to attain a high vacuum. Namely, at least one auxiliary vacuum chamber for providing a high vacuum can be installed therein.

The third and fourth vacuum chambers 966 and 967 are required for attaining a low vacuum in a manner reverse to the sequence required for attaining the necessary vacuum state when the surface-modified surface-modification substrate material 900 is discharged into the atmosphere outside the main vacuum chamber 960 as the ion beam treatment area.

A third vacuum lower than that of the main vacuum chamber 960 is attained in the third vacuum chamber 966, and a vacuum lower than the third vacuum is provided in the fourth vacuum chamber 967. The surface-modification substrate material 900 is then discharged into the atmosphere. If necessary, at least one auxiliary vacuum chamber for forming a low vacuum can be installed therein.

In a sequence reverse to that for attaining the demanded vacuum state, the surface-modified surface-modification substrate material 900 is discharged through the third vacuum chamber 966 forming a vacuum lower than that of the main vacuum chamber 960 and the fourth vacuum chamber 967 forming a vacuum lower than that of the third vacuum chamber 966. And, at least one vacuum chamber can be further installed therein to attain a vacuum lower than the previous vacuum.

The drum 980 is installed at a center of the main vacuum chamber 960 to revolve by a motor (not shown in the drawing) to transfer the surface-modification substrate material 900 of the film shape, and the first to fourth partitioning walls 920 to 923, which maintain the independent vacuums between the drum 980 and inner walls of the main vacuum chamber 960, respectively and prevent a mixed loading of the reactive gas, are installed to partition the main vacuum chamber 960.

A space between the first and second partitioning walls 920 and 921 in the main vacuum chamber 960 is the first ion beam treatment area 961, a space between the second and third partitioning walls 921 and 922 is the second ion beam treatment area 962, and a space between the third and fourth partitioning walls 922 and 923 is the third ion beam treatment area 963.

The main vacuum pump 970 and the first to sixth vacuum pumps 971 to 976 are installed to maintain the independent vacuums of the main vacuum chamber 960, the first to fourth vacuum chambers 964 to 967, and the first to third ion beam treatment areas 961 to 963, respectively.

The exhaust valves 979 are installed at the front ends of the vacuum pumps 970 to 976, respectively to improve an ion beam treatment effect and efficiency by maximizing a reaction between the reactive gas and the ion-beam-applied surface-modification substrate material 900 by controlling the vacuum exhaust speed and the exhaust speed of the reactive gas to maximize the partial pressure of the reactive gas and the time that the reactive gas stays around the surface-modification substrate material 900.

A conveyer transferring the surface-modification substrate material 900 is installed in the atmosphere, and includes a supply spool 940 supplying the surface-modification substrate material 900, a take-up spool 941 winding back the surface-modified surface-modification substrate material 900 in the atmosphere, guide rollers 942 installed in the auxiliary vacuum chambers and the main vacuum chamber 960, dance rollers 943, proximity switches 944, spreader rollers 945, and static eliminators 946.

In this case, the supply spool 940 is installed to supply the first to third ion beam treatment areas 961 to 963 with the surface-modification substrate material 900 through the first and second vacuum chambers 964 and 965 for surface modification, and the take-up spool 941 has a function of winding back the surface-modification substrate material 900 having been ion-beam-treated in the first to third ion beam treatment areas 961 to 963 through the third and fourth vacuum chambers 966 and 967.

The guide rollers 942 are installed in the first vacuum chamber 964, the second vacuum chamber 965, the main vacuum chamber 960, the third vacuum chamber 966, and the fourth vacuum chamber 967, respectively. The guide rollers has a function of guiding the surface-modification substrate material 900 to the take-up spool 941 from the supply spool 940 through the first and second vacuum chambers 964 and 965, the first to third ion beam treatment areas 961 to 963 adjacent to the drum 980, and the third and fourth vacuum chambers 966 and 967, in which the surface treatment is carried out in the first to third ion beam treatment areas 961 and 963.

Each of the dance rollers 943 is installed between the guide rollers 942 of each of the first to fourth vacuum chambers 964 to 967, and controls a tension applied to the surface-modification substrate material 900. And, the proximity switches have a function of controlling the dance rollers 943, respectively.

Each of the spreader rollers 845 is installed between the guide rollers 942 at each side of the drum 980 in the main vacuum chamber 960, and prevents the surface-modification substrate material 900 between the corresponding guide rollers 942 from being wrinkled.

The static eliminators 846 are installed between the supply spool 940 and the first vacuum chamber 964 and between the take-up spool 941 and the fourth vacuum chamber 967, and play a role of removing static electricity generated from a friction of the surface-modification substrate material 900 or an ion beam surface treatment.

The first to third ion guns 910 to 912 are installed in lower parts of the first to third ion beam treatment areas 961 to 963 centering around the drum 980, respectively.

The first to third reactive gas inlets 990 to 992 are installed between the drum 980 and the first to third ion guns 910 to 912 in the first to third ion beam treatment areas 961 to 963 to supply the reactive gas thereto, respectively. In order to maintain a gas pressure on the entire surface-modification substrate material 900 uniformly, the first to third gas distributors 950 to 952 are connected to the first to third reactive gas inlets 990 to 992, respectively.

First to third ion beam current measuring devices 930 to 932 are installed in the first to third ion beam treatment areas 961 to 962 near the drum 980 to measure ion beam currents, respectively.

The surface-modification substrate material 900 is made of polymer, ceramic, or metal, and has a film or foil shape having a long length.

In order to prevent a mixed loading of the reactive gas for generating the ion beams, the first to third ion beam treatment areas 961 to 963 are installed using the first to fourth partitioning walls 920 to 923, And, the surface modification is carried out on the surface-modification substrate material 900 in the three ion beam treatment areas independently and simultaneously.

The drum 980 adjacent to the first to third ion beam treatment areas 961 to 963 enables to operate at a temperature range of −(minus)100° C.˜300° C.

In case of cooling the drum 980, it is able to prevent the surface-modification substrate material 900 having a low glass transition temperature or a low melting point from being damaged by a heat generated from the ion beam treatment. In case of heating the drum 980, it is able to maximize the ion beam treatment effect for the surface-modification substrate material 900 having a strong thermal resistance.

The static eliminators 946 between the supply spool 940 and the first vacuum chamber 964 and between the take-up spool 941 and the fourth vacuum chamber 967 remove the static electricity generated from the friction of the surface-modification substrate material 900 and the ion beam treatment.

When the static electricity exists on a surface of the surface-modification substrate material 900, the surface-modification substrate material 900 having been irregularly surface-modified by a charging or spark of the ion beam generates the static electricity after being wound back. Hence, it is difficult to protect a user from the static electricity safely.

When the ion beam surface treatment is carried out by generating the same kind of ion beams from the first to third ion guns 910 to 912 and injecting the same kind of the reactive gas through the first to third gas distributors 950 to 952, the surface modification time of the surface-modification substrate material 900 is reduced to achieve a fast process.

Moreover, when the ion beam surface treatment is carried out by generating the different kinds of ion beams from the first to third ion guns 910 to 912 and injecting the different kinds of the reactive gases through the first to third gas distributors 950 to 952, respectively, different functional groups of the surface-modification substrate material 900 are formed to provide various effects of a single surface modification.

In order to prevent the case that the surface modification effect is changed according to a location since the partial pressure fails to be maintained uniformly on the surface-modification substrate material 900, the first to third gas distributors 950 to 952, as shown in FIG. 10 and FIG. 11, are installed to uniformly maintain the partial pressures of the reactive gas supplied to the first to third ion beam treatment areas 961 to 963 on the entire surface-modification substrate material 900.

Each of the first to third gas distributors 950 to 952 is separated from the surface-modification substrate material 900 to leave a predetermined interval in parallel from each other, and holes through which the reactive gas is supplied are disposed to face the surface of the surface-modification substrate material 900.

The surface-modification substrate material 900 is an organic material including a metal film, ceramic film, or a polymer material, and may have a curved surface. And, the organic material uses a polymer material combined with a material such as carbon, oxygen, nitrogen, fluorine, silicon, and the like.

FIGS. 10A to 10C illustrate layouts of gas distributors used in the first to eighth embodiments of the present invention.

The present invention provides a gas distributor connected to a reactive gas inlet in a vacuum chamber in order to enable a control of a partial pressure of a reactive gas as well as maintain the reactive gas on an entire surface-modification substrate material uniformly.

The related art surface treatment apparatus using the ion beam supplies the reactive gas through the pipe-shaped reactive gas inlet near the surface-modification substrate material, whereby it is difficult to maintain the partial pressure uniformly and a case that the surface modification effect varies according to a location occurs. Moreover, as a size of the surface-modification substrate material increases, such problems become more serious. 941 A gas distributor in FIG. 10 is laid in parallel with a surface-modification substrate material, and holes are disposed to face a surface of the surface-modification substrate material on which an ion beam is irradiated. An angle that the hole faces the surface of the surface-modification substrate material is fixed to be within 180° for a position vertical to the surface of the surface-modification substrate material.

A distance between the gas distributor and the surface-modification substrate material can be variously varies, and the gas distributor is preferably positioned within 500 mm from the surface of the surface-modification substrate material.

The reactive gas distributor has various shapes such as circle, rectangle, and the like in accordance with a shape or size of the surface-modification substrate material, and preferably has a rectangular shape. And, the reactive gas distributor uses such a material, which has no outgassing in the vacuum chamber and is easily processed, as stainless steel, copper, aluminum, glass, polymer, etc.

The gas distributor is made by processing a pipe, which has various diameters, to have a rectangular or circular shape. The shape of the gas distributor is variable in accordance with a size of the surface-modification substrate material so that an entire surface of the surface-modification substrate material in the gas distributor is exposed to the ion beam. Preferably, a distance between an end of the surface-modification substrate material and a hole of the gas distributor fails to exceed 300 mm.

The size of the gas distributor is made to be greater than that of the surface-modification substrate material. If the size of the gas distributor is smaller than that of the surface-modification substrate material, a shadow effect prevents the ion beam from reaching a portion of the surface-modification substrate material. Hence, the size of the gas distributor is made to be greater than that of the surface-modification substrate material to prevent the shadow effect.

FIG. 10A illustrates a layout of a gas distributor having a single reactive gas inlet.

Referring to FIG. 10A, there is one reactive gas inlet 1010 installed in a gas distributor 1000. The gas distributor 1000 is divided into first to third areas 1011 to 1013 differing from each other in diameter and number of holes 1014 according to a distance from the reactive gas inlet 1010 to make a reactive gas flow on a surface-modification substrate material (not shown in the drawing).

In the area adjacent to the reactive gas inlet 1010, the diameter and number of holes 1014 decrease. The number and diameter of the holes 1014 increase as the holes 1014 get far from the reactive gas inlet 1010.

The number and diameter of holes of the gas distributor 1000, as shown in FIG. 10A, increase in order of the first to third areas 1011 to 1013.

It is able to supply the reactive gas uniformly to a location far from the reactive gas inlet 1010 by increasing the diameter and number of the holes getting farther from the reactive gas inlet 1010. Moreover, various variations of the number and diameter are available according to a size of the gas distributor.

FIG. 10B illustrates a layout of a gas distributor having a couple of reactive gas inlets.

Referring to FIG. 10B, in case that a size of a surface-modification substrate material (not shown in the drawing) is big, a first reactive gas inlet 1021 and a second reactive gas inlet 1022 are installed to confront each other at a gas distributor 1020. And, the gas distributor 1020 is divided into first and second areas 1023 and 1024 differing in diameter and number of holes 1025 according to a distance from the first or second reactive gas inlet 1021 or 1022.

The number of the holes 1025 in the first area 1023 of the gas distributor 1020, as shown in FIG. 10B, is smaller than that in the second area 1024, and the diameter of the holes 1025 in the first area 1023 of the gas distributor 1020 is smaller than that in the second area 1024. It is able to supply the surface-modification substrate material with the reactive gas uniformly by increasing the diameter and number of the holes 1025 getting farther from the first and second gas inlets 1021 and 1022.

FIG. 10C illustrates a layout of a gas distributor having four reactive gas inlets.

Referring to FIG. 10C, in case that a size of a surface-modification material (not shown in the drawing) is big, first to fourth reactive gas inlets 1031 to 1034 are installed at four faces of a gas distributor 1030, respectively to make a reactive gas flow uniformly.

In case that several reactive gas inlets are installed at the gas distributor 1030, it is able to maintain a partial pressure of the reactive gas uniformly even if the diameter and number of holes 1035, which are different form that of FIG. 10A or FIG. 10B, are maintained uniformly. Of course, in case of FIG. 10C, the diameter and number of the holes 1035 can be variously adjusted in accordance with a size of the gas distributor 1030.

It is advantageous to maintain a uniform partial pressure as the number of the reactive gas inlets of the gas distributor 1030 increases. Preferably, it is efficient to install 2˜4 reactive gas inlets.

FIG. 11A and FIG. 11B illustrate layouts of gas distributors each having an ion beam current measuring device used in the present invention.

In order to enable a control of a partial pressure of a reactive gas and maintain the reactive gas uniformly on an entire surface-modification substrate material, a gas distributor connected to a reactive gas inlet in a vacuum chamber is provided. Specifically, for the present invention continuously surface-treating a surface-modification substrate material having a film shape or the like for mass production, it is advantageous to use a gas distributor having an ion beam current measuring device installed therein.

It is able to measure a real-time variation of an ion beam current for a time of ion beam surface treatment by installing an ion beam current measuring device in a gas distributor. And, it is able to maintain an effect of surface modification uniformly by controlling an ion amount arriving at a surface of a surface-modification substrate material from an ion gun in accordance with necessity.

A size of the gas distributor is made bigger than that of the surface-modification substrate material. The surface-modification substrate material continuously moves even if the gas distributor is smaller than the surface-modification substrate material. Hence, the ion beam fails to reach a certain portion of the surface-modification substrate material due to the shadow effect of the gas distributor. In order to apply the ion beam to the entire surface-modification substrate material uniformly, the gas distributor should be made bigger than the surface-modification substrate material.

The ion beam current measuring device is installed at a support traversing a cavity area of the gas distributor. The support brings about a screen effect that the ion beam fails to reach a portion of the surface-modification substrate material. Yet, in case that the surface-modification substrate material fails to be fixed but move continuously, the screen effect of the ion beam can be ignored.

Preferably, the ion beam current measuring device is attached to the support installed at a central cavity area of the gas distributor, confronts holes of the gas distributor, and is located in a direction facing the ion gun. In this case, regardless of an angle that the holes are located, the ion beam current measuring unit is disposed to be vertical to the ion beam. A size of the support having the ion beam current measuring unit attached thereto is preferably minimized to maximize an ion beam irradiation area.

FIG. 11A illustrates a layout of a gas distributor having a couple of reactive gas inlets and an ion beam current measuring device installed thereon.

Referring to FIG. 11A, a first reactive gas inlet 1101 and a second reactive gas inlet 1102 are installed to confront each other at a gas distributor 1100. And, the gas distributor 1100 is divided into first and second areas 1103 and 1104 differing in diameter and number of holes 1105 according to a distance from the first or second reactive gas inlet 1101 or 1102.

A support 1106 traversing a cavity area of the gas distributor 1100 is installed, and an ion beam current measuring device 1107 is attached onto the support 1106.

The number of the holes 1105 in the first area 1103 of the gas distributor 1100, as shown in FIG. 11A, is smaller than that in the second area 1104, and the diameter of the holes 1105 in the first area 1103 of the gas distributor 1100 is smaller than that in the second area 1104. It is able to supply the surface-modification substrate material with the reactive gas uniformly by increasing the diameter and number of the holes 1105 getting farther from the first and second gas inlets 1101 and 1102.

FIG. 11B illustrates a layout of a gas distributor having four reactive gas inlets and an ion beam current measuring device installed thereon.

Referring to FIG. 11B, in case that a size of a surface-modification material (not shown in the drawing) is big, first to fourth reactive gas inlets 1111 to 1114 are installed at four faces of a gas distributor 1110, respectively to make a reactive gas flow uniformly.

In case that several reactive gas inlets are installed at the gas distributor 1110, it is able to maintain a partial pressure of the reactive gas uniformly even if the diameter and number of holes 1115 are maintained uniformly. Of course, in case of FIG. 10C, the diameter and number of the holes 1115 can be variously adjusted in accordance with a size of the gas distributor 1110.

A support 1116 traversing a cavity area of the gas distributor 1110 is installed and an ion beam current measuring device 1117 is attached onto the support 1116.

In order to maintain the partial pressure of the reactive gas and the ion beam current uniformly for the surface-modification substrate material which has a large area and is continuously surface-treated, the support 1116 having the ion beam current measuring device 1117 installed thereon can be replaced by a pipe having a plurality of holes 1115 thereon.

In this case, the ion beam current measuring device 1117 is attached to the pipe used as the support 1116 connected to the gas distributor 1110, confronts the holes 1115 of the gas distributor 1110, and is located in a direction facing an ion gun (not shown in the drawing).

If an area of the surface-modification substrate material is so big that an area exposed to the ion beam is big, a plurality of the ion beam current measuring devices 1117 can be simultaneously installed on the support 116 to leave a predetermined interval from each other as well as the number of the reactive gas inlets can be increased to maintain the uniform partial pressure of the reactive gas.

Accordingly, an apparatus for modifying a surface of a material using an ion beam according to the present invention has the following advantages and effects as follows.

First of all, the gas distributor is connected to the reactive gas inlet supplying the reactive gas for the ion beam treatment to maintain the reactive gas uniformly. And, the exhaust valve is installed at the front end of the vacuum pump to increase the time that the reactive gas stays on the surface of the surface-modification substrate material and the partial pressure of the reactive gas. Hence, the present invention enables to carry out the surface treatment on the surface-modification substrate material homogeneously and effectively.

Secondly, the drum for transferring the surface-modification substrate material and a plurality of the ion beam treatment areas are installed in the vacuum chamber. When the ion beam surface treatment is carried out by injecting the same kind of the reactive gas, it is able to reduce a surface treatment time of the surface-modification substrate material to achieve a fast process. When the ion beam surface treatment is carried out by injecting the different kinds of the reactive gases, it is able to form different functional groups of the surface-modification substrate material to provide various effects with a single surface treatment.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. An apparatus for modifying a surface of a material, comprising:
a vacuum chamber;
an ion gun generating an ion beam in the vacuum chamber;
a surface-modification substrate material to which the ion beam is applied from the ion gun in the vacuum chamber;
a reactive gas inlet leaving a predetermined interval from the surface-modification substrate material to supply a reactive gas;
a gas distributor connected to the reactive gas inlet to maintain a partial pressure of the reactive gas uniformly on an entire surface of the surface-modification substrate material;
a vacuum means for generating a vacuum of the vacuum chamber; and
an exhaust valve installed at a front end of the vacuum means to control an exhaust speed of the reactive gas.

2. The apparatus of claim 1, wherein the surface-modification substrate material is supported by a holder insulating the surface-modification substrate material from the vacuum chamber electrically and enabling to apply a voltage thereto.

3. The apparatus of claim 1, wherein the vacuum chamber is partitioned by a first partitioning wall around the ion gun and a second partitioning wall between a periphery of the surface-modification substrate material and a middle part of the vacuum chamber.

4. The apparatus of claim 1, wherein a holder supporting the surface-modification substrate material and operating by a motor is installed to agitate the surface-modification substrate material of a powder phase.

5. The apparatus of claim 3, wherein portions of the first and second partitioning walls through that the ion beam passes are open.

6. The apparatus of claim 2, wherein the ion gun and the holder are installed in lower and upper parts of the vacuum chamber, respectively and the reactive gas inlet entering the vacuum chamber through a bottom of the vacuum chamber is installed in a periphery of the holder.

7. The apparatus of claim 1, wherein the gas distributor leaves a predetermined interval from the surface-modification substrate material in parallel and a plurality of holes, from which the reactive gas flows out, of the gas distributor are disposed to face a surface of the surface-modification substrate material.

8. The apparatus of claim 7, wherein a size of the gas distributor is smaller than that of the surface-modification substrate material.

9. The apparatus of claim 8, wherein the reactive gas inlet is connected to the gas distributor and diameters and numbers of the holes vary in accordance with a distance separated from the reactive gas inlet.

10. The apparatus of claim 9, wherein the numbers and diameters of the holes in a distant area from the reactive gas inlet are greater than those in an area closer to the reactive gas inlet.

11. The apparatus of claim 8, wherein at least one of the reactive gas inlets are connected to the gas distributor.

12. The apparatus of claim 8, wherein an ion beam current measuring device is installed at the gas distributor.

13. The apparatus of claim 1, wherein the surface-modification substrate material is a polymer material containing carbon and hydrogen and selected from the group consisting of PE, PP, PS, etc.

14. The apparatus of claim 1, wherein the surface-modification substrate material is a polymer material containing carbon, hydrogen, and oxygen selected from the group consisting of polyesters, polycarbonates, polyethers, PC, PET, PMMA, etc.

15. The apparatus of claim 1, wherein the surface-modification substrate material is a material containing carbon, hydrogen, oxygen, and nitrogen selected from the group consisting of polyamines, polyimides, polyurethanes, PA, PI, PU, etc.

16. The apparatus of claim 1, wherein the surface-modification substrate material is a polymer material containing carbon, hydrogen, and nitrogen selected from the group consisting of polyimines, phenol-and-amine-formaldehydes (polyethylene imine), etc.

17. The apparatus of claim 1, wherein the surface-modification substrate material is a polymer material containing carbon, hydrogen, oxygen, and sulfur selected from the group consisting of polyester sulfone (polysulfones), PES, etc.

18. The apparatus of claim 1, wherein the surface-modification substrate material is a polymer material containing carbon, hydrogen, and fluorine selected from the group consisting of polyvinylidene fluoride (PVDF), etc.

19. The apparatus of claim 1, wherein the surface-modification substrate material is a polymer material containing carbon and fluorine selected from the group consisting of PTFE, etc.

20. The apparatus of claim 1, wherein the surface-modification substrate material is a polymer material containing carbon, hydrogen, and chlorine selected from the group consisting of polyvinyl chloride, polyvinylidene chloride (PVDC), etc.

21. The apparatus of claim 1, wherein the surface-modification substrate material is a polymer material containing carbon, hydrogen, oxygen, and silicon selected from the group consisting of polydimethylsiloxane, polycarbonate-siloxane, or silicon rubber, etc.

22. An apparatus for modifying a surface of a material, comprising:
a vacuum chamber;
at least two ion guns generating ion beams respectively in the vacuum chamber;
a conveyer transferring a surface-modification substrate material to which the ion beams are irradiated from the ion guns in the vacuum chamber;
a reactive gas inlet supplying a reactive gas;
at least two gas distributors corresponding to the number of the ion guns, each of the gas distributors connected to the reactive gas inlet to maintain a partial pressure of the reactive gas uniformly on an entire surface of the surface-modification substrate material;
a vacuum means for generating a vacuum of the vacuum chamber; and
an exhaust valve installed at a front end of the vacuum means to control an exhaust speed of the reactive gas.

23. The apparatus of claim 22, wherein the ion guns are first and second ion guns, respectively and the ion beams from the first and second ion guns are irradiated on front and rear faces of the surface-modification substrate material, respectively.

24. The apparatus of claim 22, wherein the two gas distributors are first and second gas distributors, respectively and the first and second distributors are installed near the front and rear faces of the surface-modification substrate material.

25. The apparatus of claim 22, the conveyer comprising:
a supply roller supplying the surface-modification substrate material into the vacuum chamber to surface-treat the surface-modification substrate material continuously;
a take-up roller winding back the surface-treated surface-modification substrate material;
a guide roller normally transferring the surface-modification substrate material to the take-up roller from the supply roller through an ion beam treatment area; and
a device for controlling a supply speed or tension of the surface-modification substrate material.

26. The apparatus of claim 24, wherein each of the first and second gas distributors confronting each other leaves a predetermined interval from the surface-modification substrate material in parallel and a plurality of holes of the first and second gas distributors are disposed to face the surfaces of the surface-modification substrate material.

27. The apparatus of claim 26, wherein a number and diameters of the holes vary in accordance with a distance from the reactive gas inlet connected to the corresponding gas distributor.

28. The apparatus of claim 26, wherein an angle that each of the holes faces the corresponding surface of the surface-modification substrate material is fixed within 180° for a position vertical to the corresponding surface of the surface-modification substrate material.

29. The apparatus of claim 26, wherein the gas distributor is left apart from the surface-modification substrate material within 500 mm and an end of the surface-modification substrate material is not separated from the holes of the gas distributor over 300 mm.

30. The apparatus of claim 26, wherein an ion beam current measuring device is installed on a support traversing a cavity area of the gas distributor.

31. The apparatus of claim 22, wherein the ion guns are first and second ion guns, respectively and the ion beams from the first and second ion guns are irradiated on the front and rear faces of the surface-modification substrate material.

32. An apparatus for modifying a surface of a material, comprising:
a main vacuum chamber;
an auxiliary vacuum chamber connected to the main vacuum chamber to have a vacuum degree lower than that of the main vacuum chamber;
an ion gun generating an ion beam in the main vacuum chamber;
a surface-modification substrate material to which the ion beam is applied from the ion gun in the main vacuum chamber;
a conveyer transferring the surface-modification substrate material;
a reactive gas inlet leaving a predetermined interval from the surface-modification substrate material to supply a reactive gas;
a gas distributor connected to the reactive gas inlet to maintain a partial pressure of the reactive gas uniformly on an entire surface of the surface-modification substrate material;
a vacuum means for generating a vacuum of the main and auxiliary vacuum chambers; and
an exhaust valve installed at a front end of the vacuum means to control an exhaust speed of the reactive gas.

33. The apparatus of claim 32, wherein the auxiliary vacuum chamber is installed plurally.

34. The apparatus of claim 32, the conveyer comprising:
a supply roller supplying the surface-modification substrate material into the vacuum chamber to surface-treat the surface-modification substrate material continuously;
a take-up roller winding back the surface-treated surface-modification substrate material;
a guide roller normally transferring the surface-modification substrate material to the take-up roller from the supply roller through an ion beam treatment area; and
a device for controlling tension of the surface-modification substrate material.

35. The apparatus of claim 32, wherein the gas distributor leaves a predetermined interval from the surface-modification substrate material in parallel and a plurality of holes, from which the reactive gas flows out, of the gas distributor are disposed to face a surface of the surface-modification substrate material.

36. The apparatus of claim 35, wherein a number and diameters of the holes vary in accordance with a distance separated from the reactive gas inlet connected to the gas distributor.

37. An apparatus for modifying a surface of a material, comprising:
a main vacuum chamber;
an ion gun generating an ion beam in the main vacuum chamber;
a plate-shaped surface-modification substrate material to which the ion beam is applied from the ion gun in the main vacuum chamber;
a first auxiliary vacuum chamber at one side of the main vacuum chamber to make the surface-modification substrate material stand by or supply the main vacuum chamber with the surface-modification substrate material;
a second auxiliary vacuum chamber at the other side of the main vacuum chamber to unload the surface-modification substrate material;
a reactive gas inlet leaving a predetermined interval from the surface-modification substrate material to supply a reactive gas;
a gas distributor connected to the reactive gas inlet to maintain a partial pressure of the reactive gas uniformly on an entire surface of the surface-modification substrate material;
a vacuum means for generating a vacuum of the main, first, and second vacuum chambers; and
an exhaust valve installed at a front end of the vacuum means to control an exhaust speed of the reactive gas.

38. The apparatus of claim 37, wherein each of the first and second auxiliary vacuum chambers comprises a vertically movable rod enabling to move upward and downward and a holder connected to the vertically movable rod to receive a plurality of plate-shaped surface-modification substrate materials therein and wherein the apparatus further comprises a conveyer system transferring the surface-modification substrate materials to the second auxiliary vacuum chamber from the first auxiliary vacuum chamber through the main vacuum chamber.

39. The apparatus of claim 37, comprising:
a first ion gun in an upper part of the main vacuum chamber;
a second ion gun in a lower part of the main vacuum chamber;
a support holder supporting the surface-modification substrate material to expose front and rear faces of the surface-modification substrate material;
a first reactive gas inlet between a front face of the support holder and the first ion gun; and
a second reactive gas inlet between a rear face of the support holder and the second ion gun.

40. The apparatus of claim 37, wherein the gas distributor leaves a predetermined interval from the surface-modification substrate material in parallel and a plurality of holes, from which the reactive gas flows out, of the gas distributor are disposed to face a surface of the surface-modification substrate material.

41. The apparatus of claim 40, wherein a number and diameters of the holes vary in accordance with a distance separated from the reactive gas inlet connected to the gas distributor.

42. The apparatus of claim 37, wherein the first auxiliary vacuum chamber is installed at one side of the main vacuum chamber to make the plate-shaped surface-modification substrate material stand by or supply the main vacuum chamber with the surface-modification substrate material and the second auxiliary vacuum chamber is installed at the other side of the main vacuum chamber to unload the plate-shaped surface-modification substrate material.

43. An apparatus for modifying a surface of a material, comprising:
a vacuum chamber;
a plurality of ion beam treatment areas having a drum located at a center of the vacuum chamber, the ion beam treatment areas separated by a plurality of partitioning walls;
a plurality of ion guns generating ion beams in a plurality of the ion beam treatment areas, respectively;
at least one reactive gas inlet supplying a plurality of the ion beam treatment areas with a reactive gas, respectively;
at least one gas distributor connected to the reactive gas inlet to maintain a partial pressure of the reactive gas uniformly on an entire surface of a surface-modification substrate material;
a conveyer transferring the surface-modification substrate material to a plurality of the ion beam treatment areas;
a vacuum means for generating vacuums of the vacuum chamber and a plurality of the ion beam treatment areas independently; and
an exhaust valve installed at a front end of the vacuum means to control an exhaust speed of the reactive gas.

44. The apparatus of claim 43, wherein the ion gun, reactive gas inlet, and gas distributor are installed in each of a plurality of the ion beam treatment areas.

45. The apparatus of claim 43, the conveyer comprising:
a supply roller supplying the surface-modification substrate material into the vacuum chamber to surface-treat the surface-modification substrate material continuously;
a take-up roller winding back the surface-treated surface-modification substrate material;
a plurality of rollers normally transferring the surface-modification substrate material to the take-up roller from the supply roller through a plurality of the ion beam treatment areas; and
a device for controlling tension of the surface-modification substrate material.

46. An apparatus for modifying a surface of a material, comprising:
a vacuum chamber;
a plurality of ion beam treatment areas having a drum located at a center of the vacuum chamber, the ion beam treatment areas separated by a plurality of partitioning walls;
a plurality of ion guns generating ion beams in a plurality of the ion beam treatment areas, respectively;
at least one reactive gas inlet supplying a plurality of the ion beam treatment areas with a reactive gas, respectively;
at least one gas distributor connected to the reactive gas inlet to maintain a partial pressure of the reactive gas uniformly on an entire surface of a surface-modification substrate material;
a first auxiliary vacuum chamber for attaining a high vacuum state required for supplying the vacuum chamber with the surface-modification substrate material in an atmosphere;
a second auxiliary vacuum chamber for attaining a low vacuum state required for discharging the surface-modification substrate material into the atmosphere wherein the surface-modification substrate material is surface-treated in the vacuum chamber;
a conveyer transferring the surface-modification substrate material; and
a vacuum means for generating vacuums of the vacuum chamber and a plurality of the ion beam treatment areas independently.

47. The apparatus of claim 46, wherein the ion gun, reactive gas inlet, and gas distributor are installed in each of a plurality of the ion beam treatment areas.

48. The apparatus of claim 46, the conveyer comprising:
a supply roller supplying the surface-modification substrate material into the vacuum chamber to surface-treat the surface-modification substrate material continuously;
a take-up roller winding back the surface-treated surface-modification substrate material;
a plurality of rollers normally transferring the surface-modification substrate material to the take-up roller from the supply roller through a plurality of the ion beam treatment areas; and
a device for controlling tension of the surface-modification substrate material.
